(19) United States
(12) Patent Application Publication
(10) Pub. No.: US 2025/0294746 A1
(43) Pub. Date: Sep. 18, 2025

(54) THREE-DIMENSIONAL SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: Kohji Kanamori, Suwon-si (KR); Jeehoon Han, Suwon-si (KR); Taeyoon Hong, Suwon-si (KR)

(21) Appl. No.: 18/903,114

(22) Filed: Oct. 1, 2024

(30) Foreign Application Priority Data
Mar. 13, 2024 (KR) 10-2024-0035347

(51) Int. Cl. H10B 43/27; H10B 41/27; H10B 41/35; H10B 41/41; H10B 43/35; H10B 43/40

(52) U.S. Cl. CPC H10B 43/27; H10B 41/27; H10B 41/35; H10B 41/41; H10B 43/35; H10B 43/40

(57) ABSTRACT

A three-dimensional semiconductor memory device may include a first cell array structure on a substrate, the first cell array structure including a plurality of first gate electrodes, which are stacked in a first direction perpendicular to a top surface of the substrate, a second cell array structure on the first cell array structure, the second cell array structure including a plurality of second gate electrodes, which are stacked in the first direction, a first penetration via in the first cell array structure and extending in the first direction, and a second penetration via that is in contact with a surface of the first penetration via and extends from the surface of the first penetration via in the first cell array structure into the second cell array structure in the first direction.

### CROSS-REFERENCE TO RELATED APPLICATIONS

This U.S. non-provisional patent application claims priority under 35 U.S.C. § 119 to Korean Patent Application No. 10-2024-0035347, filed on Mar. 13, 2024, in the Korean Intellectual Property Office, the entire contents of which are hereby incorporated by reference.

### FIELD OF THE INVENTION

The present disclosure relates to a three-dimensional semiconductor memory device and an electronic system including the same.

### BACKGROUND OF THE INVENTION

A semiconductor device capable of storing a large amount of data may be required for data storage of an electronic system. Higher integration of semiconductor devices is required to satisfy consumer demand for large data storing capacity, superior performance, and inexpensive prices. In the case of two-dimensional or planar semiconductor devices, since integration may be primarily determined by the area occupied by a unit memory cell, integration may be influenced by the level of precision of a fine pattern forming technology. However, expensive process equipment may be required to increase pattern fineness, which may set practical limitations on increasing integration for two-dimensional or planar semiconductor devices. Thus, three-dimensional semiconductor memory devices including three-dimensionally arranged memory cells have been proposed.

### SUMMARY

An embodiment of the inventive concept provides a three-dimensional semiconductor memory device with improved productivity and an electronic system including the same.

According to an embodiment of the inventive concept, a three-dimensional (3D) semiconductor memory device may include a first cell array structure on a substrate, the first cell array structure including a plurality of first gate electrodes that are stacked in a first direction perpendicular to a top surface of the substrate, a second cell array structure on the first cell array structure, the second cell array structure including a plurality of second gate electrodes that are stacked in the first direction, a first penetration via in the first cell array structure and extending in the first direction, and a second penetration via that is in contact with a top surface of the first penetration via in the first cell array structure and extends from the top surface of the first penetration via into the second cell array structure in the first direction.

According to an embodiment of the inventive concept, a three-dimensional (3D) semiconductor memory device may include a peripheral circuit structure on a substrate, a first cell array structure on the peripheral circuit structure, the first cell array structure including a first stack including a plurality of first gate electrodes that are stacked in a first direction perpendicular to a top surface of the substrate, a second cell array structure on the first cell array structure, the second cell array structure including a second stack including a plurality of second gate electrodes that are stacked in the first direction, a first penetration via extending into the first stack in the first direction, and a second penetration via extending into the second stack in the first direction. The second penetration via may be in contact with a top surface of the first penetration via free of bonding pads therebetween and may be electrically connected to the peripheral circuit structure through the first penetration via.

According to an embodiment of the inventive concept, an electronic system may include a three-dimensional semiconductor memory device, and a controller that is electrically connected to the three-dimensional semiconductor memory device through an input/output pad and is configured to control the three-dimensional semiconductor memory device. The three-dimensional semiconductor memory device may include a first cell array structure on a substrate, the first cell array structure including a plurality of first gate electrodes that are stacked in a first direction perpendicular to a top surface of the substrate, a second cell array structure on the first cell array structure, the second cell array structure including a plurality of second gate electrodes that are stacked in the first direction, a first penetration via in the first cell array structure and extending in the first direction, a second penetration via that is in contact with a top surface of the first penetration via in the first cell array structure and extends from the top surface of the first penetration via into the second cell array structure in the first direction.

### BRIEF DESCRIPTION OF THE DRAWINGS

FIG. 1A is a block diagram illustrating a three-dimensional semiconductor memory device according to an embodiment of the inventive concept.

FIG. 1B is a schematic diagram illustrating an electronic system including a three-dimensional semiconductor memory device, according to an embodiment of the inventive concept.

FIG. 1C is a perspective view schematically illustrating an electronic system including a three-dimensional semiconductor memory device according to an embodiment of the inventive concept.

FIGS. 1D and 1E are sectional views, which are taken along a line I-I′ of FIG. 1C to illustrate a semiconductor package including a three-dimensional semiconductor memory device according to an embodiment of the inventive concept.

FIG. 2 is a sectional view illustrating a three-dimensional semiconductor memory device according to an embodiment of the inventive concept.

FIGS. 3A and 3B are enlarged sectional views, each of which illustrates a portion ‘P1’ of FIG. 2.

FIG. 4 is a sectional view illustrating a three-dimensional semiconductor memory device according to an embodiment of the inventive concept.

FIG. 5 is a sectional view illustrating a three-dimensional semiconductor memory device according to an embodiment of the inventive concept.

FIG. 6 is an enlarged sectional view illustrating a portion ‘P2’ of FIG. 5.

FIG. 7 is a sectional view illustrating a three-dimensional semiconductor memory device according to an embodiment of the inventive concept.

FIG. 8 is an enlarged sectional view illustrating a portion ‘P3’ of FIG. 7.

FIG. 9 is a sectional view illustrating a three-dimensional semiconductor memory device according to an embodiment of the inventive concept.

FIGS. 10, 11, 12, 13, 14, 15, 16, 17, 18, and 19 are sectional views illustrating a method of fabricating a three-dimensional semiconductor memory device, according to an embodiment of the inventive concept.

### DETAILED DESCRIPTION

Example embodiments of the inventive concepts will now be described more fully with reference to the accompanying drawings, in which example embodiments are shown. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

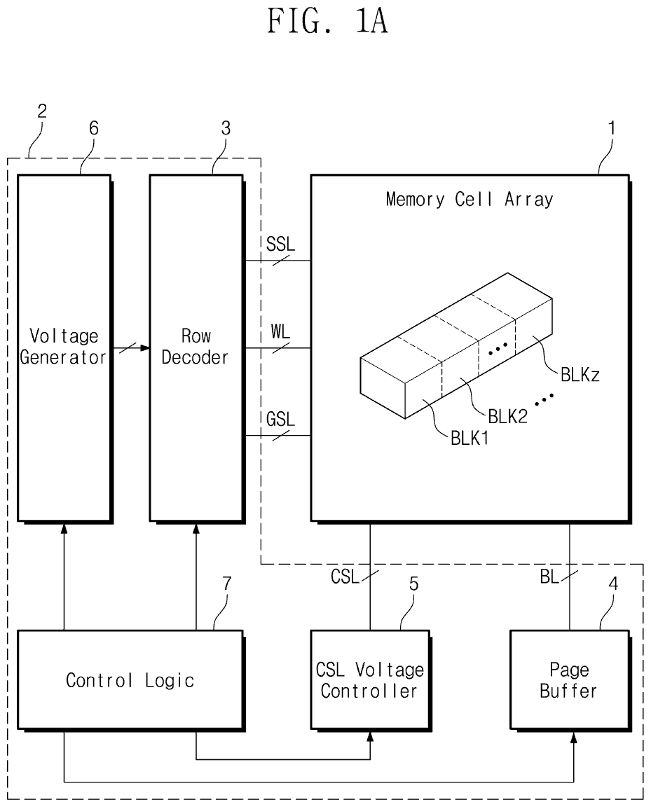

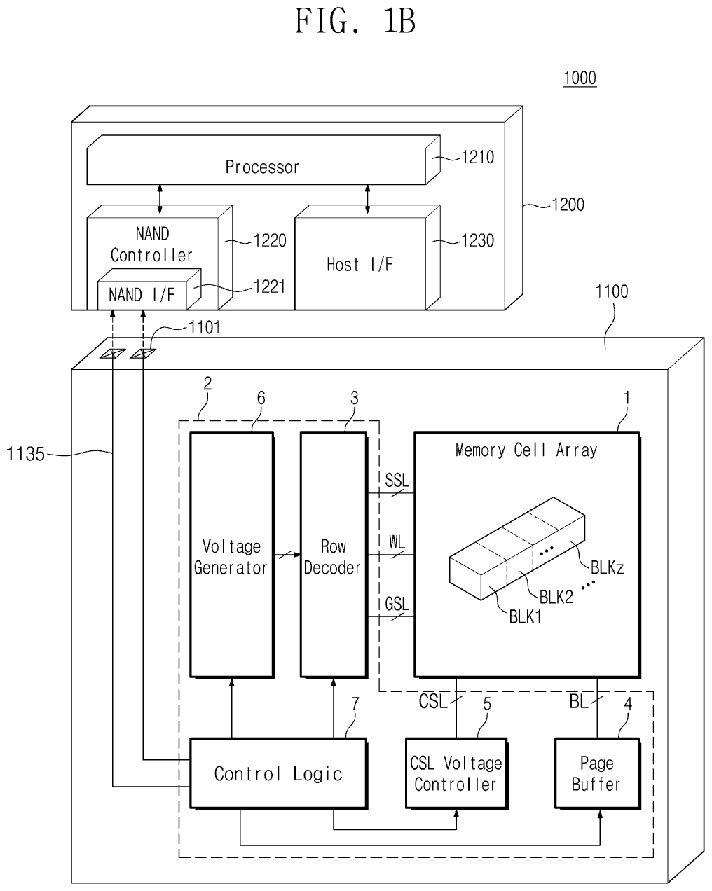

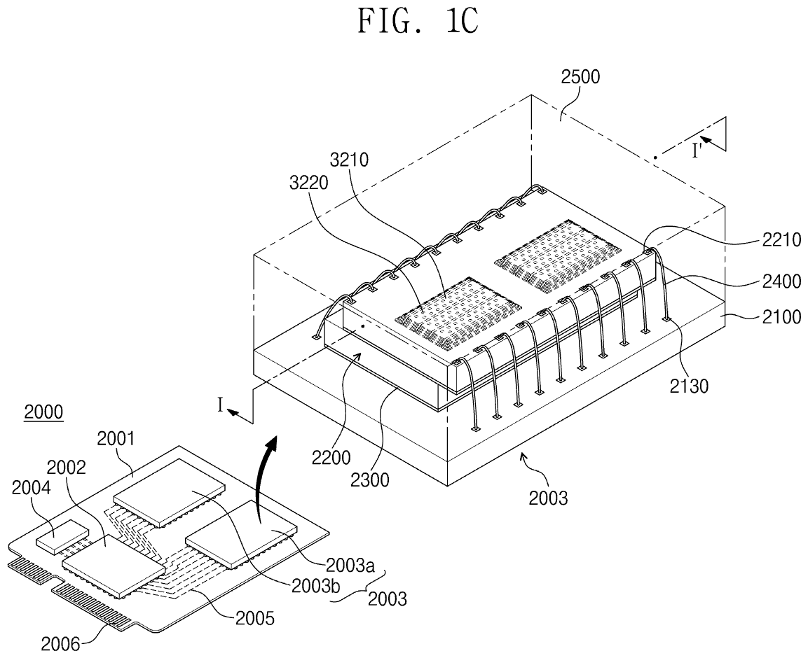

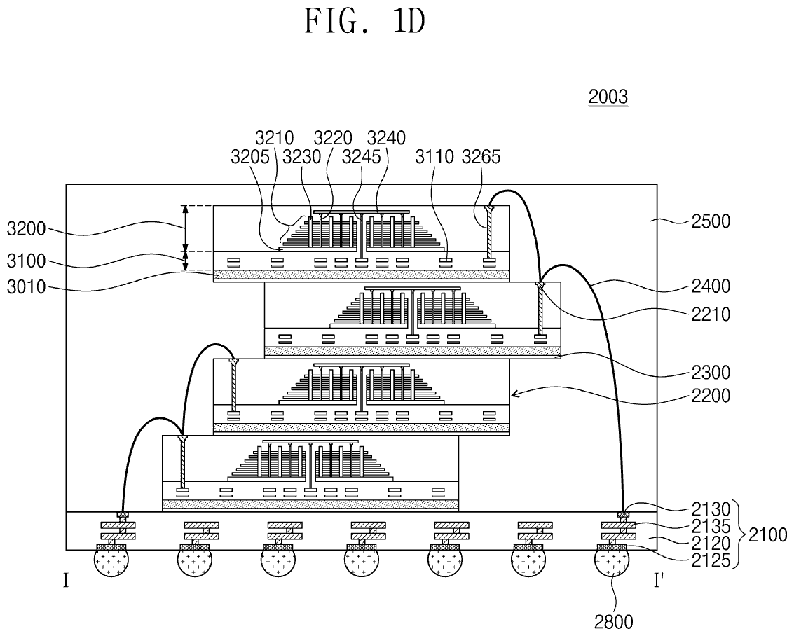

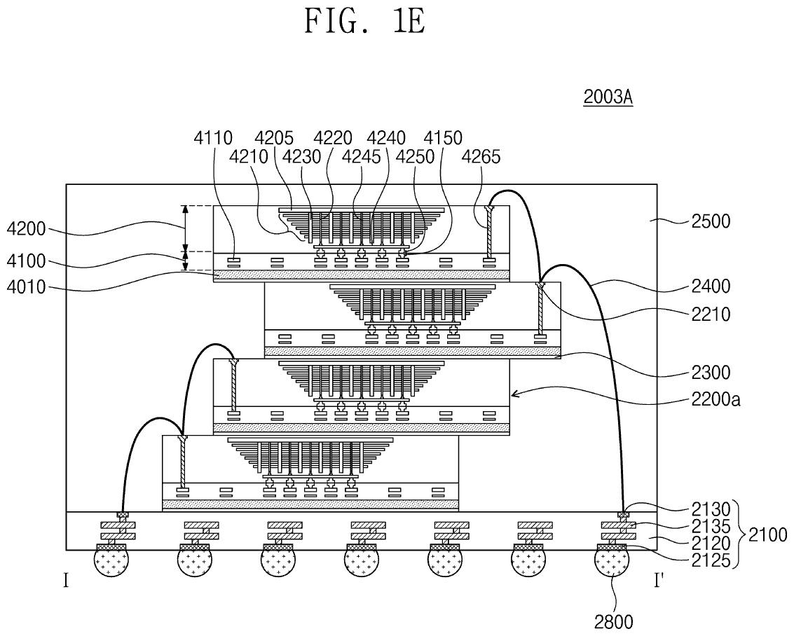

FIG. 1A is a block diagram illustrating a three-dimensional semiconductor memory device according to an embodiment of the inventive concept.

Referring to FIG. 1A, a three-dimensional semiconductor memory device may include a memory cell array 1 and a peripheral circuit 2, which is used to control the memory cell array 1. The peripheral circuit 2 may include a row decoder 3, a page buffer 4, a common source line (CSL) voltage controller 5, a voltage generator 6, and a control logic 7.

The memory cell array I may include a plurality of memory blocks BLK1-BLKz. Each of the memory blocks BLK1-BLKz may include a plurality of memory cells which are three-dimensionally arranged. For example, the memory blocks BLK1-BLKz may include a plurality of structures, in which memory cells are stacked. Data reading or writing operations on one of the memory blocks BLK1-BLKz may be performed in response to a block selection signal. An erase operation on the memory cells may be performed on each of the memory blocks of the memory cell array 1.

In an embodiment, the three-dimensional semiconductor memory device may be a vertical-type NAND FLASH memory device. For the vertical-type NAND FLASH memory device, the memory blocks BLK1-BLKz may include a plurality of cell strings that are provided to form a NAND structure.

The row decoder 3 may be configured to decode address information transmitted from the outside and to select at least one of the memory blocks BLK1, BLK2, . . . , and BLKz and to select word lines WL, a string selection line SSL, and a ground selection line GSL in the selected memory block, based on the decoded address information. The row decoder 3 may deliver an operation voltage to the word line WL of the selected memory block.

The page buffer 4 may be connected to the memory cell array 1 through bit lines BL and may be used to determine data stored in the memory cells.

The page buffer 4 may be used as a writing driver applying voltages, which correspond to the data to be stored in the memory cell array 1, to the bit lines BL, in a programming operation, and may be used as a sensing amplifier sensing data stored in the memory cell array 1, in a reading operation. The operations of the page buffer 4 may be controlled by control signals that are transmitted from the control logic 7.

The CSL voltage controller 5 may be connected to the memory cell array 1 through a common source line CSL. The CSL voltage controller 5 may apply a common source voltage (e.g., a power or ground voltage) to the common source line CSL, under the control of the control logic 7.

The voltage generator 6 may generate voltages (e.g., a program voltage, a reading voltage, an erase voltage, a pass voltage, a verifying voltage, and so forth), which are required for an internal operation of the memory cell array 1, under the control of the control logic 7.

The control logic 7 may generate various control signals, which are required for the programming, reading, and erasing operations on the memory cell array 1, based on command, address, and control signals.

FIG. 1B is a schematic diagram illustrating an electronic system including a three-dimensional semiconductor memory device, according to an embodiment of the inventive concept.

Referring to FIG. 1B, an electronic system 1000 according to an embodiment of the inventive concept may include a three-dimensional semiconductor memory device 1100 and a controller 1200, which are electrically connected to each other. The electronic system 1000 may be a storage device including one or more three-dimensional semiconductor memory devices 1100 or an electronic device including the storage device. For example, the electronic system 1000 may be a solid state drive (SSD) device, a universal serial bus (USB), a computing system, a medical system, or a communication system, in which at least one three-dimensional semiconductor memory device 1100 is provided.

The three-dimensional semiconductor memory device 1100 may be a nonvolatile memory device (e.g., a NAND FLASH memory device). The three-dimensional semiconductor memory device 1100 may include the memory cell array 1 and the peripheral circuit 2, which is used to control the memory cell array 1, as described with reference to FIG. 1A. The peripheral circuit 2 may include the row decoder 3, the page buffer 4, the CSL voltage controller 5, the voltage generator 6, and the control logic 7.

The three-dimensional semiconductor memory device 1100 may communicate with the controller 1200 through input/output pads 1101 electrically connected to the control logic 7. The input/output pads 1101 may be electrically connected to the control logic 7 through input/output interconnection lines 1135.

The controller 1200 may include a processor 1210, a NAND controller 1220, and a host interface 1230. In an embodiment, the electronic system 1000 may include a plurality of three-dimensional semiconductor memory devices 1100, and in this case, the controller 1200 may be used to control the three-dimensional semiconductor memory devices 1100.

The processor 1210 may control the overall operation of the electronic system 1000 including the controller 1200. Based on a specific firmware, the processor 1210 may execute operations of controlling the NAND controller 1220 and accessing the three-dimensional semiconductor memory device 1100. The NAND controller 1220 may include a NAND interface 1221, which is used for communication with the three-dimensional semiconductor memory device 1100. The NAND interface 1221 may be configured to transmit and receive control commands, which are used to control the three-dimensional semiconductor memory device 1100, and to transmit and receive data, which are written in or read from the memory cells of the three-dimensional semiconductor memory device 1100. The host interface 1230 may be configured to allow for communication between the electronic system 1000 and an external host. If a control command is provided from an external host through the host interface 1230, the processor 1210 may control the three-dimensional semiconductor memory device 1100 in response to the control command.

FIG. 1C is a perspective view schematically illustrating an electronic system including a three-dimensional semiconductor memory device according to an embodiment of the inventive concept.

Referring to FIG. 1C, an electronic system 2000 may include a main substrate 2001 and a controller 2002, one or more semiconductor packages 2003, and a DRAM 2004, which are mounted on the main substrate 2001. The semiconductor package 2003, the DRAM 2004, and the controller 2002 may be connected to each other through interconnection patterns 2005, which are formed in the main substrate 2001.

The main substrate 2001 may include a connector 2006, which includes a plurality of pins coupled to an external host. In the connector 2006, the number and the arrangement of the pins may be changed depending on a communication interface between the electronic system 2000 and the external host. In an embodiment, the electronic system 2000 may communicate with the external host, in accordance with one or more interfaces, such as universal serial bus (USB), peripheral component interconnect express (PCI-Express), serial advanced technology attachment (SATA), universal flash storage (UFS) M-Phy, or the like. In an embodiment, the electronic system 2000 may be driven by electrical power, which is supplied from the external host through the connector 2006. The electronic system 2000 may further include a power management integrated circuit (PMIC) that is used to separately supply the electric power, which is provided from the external host to the controller 2002 and the semiconductor package 2003.

The controller 2002 may control a writing or reading operation on the semiconductor package 2003 and may improve an operation speed of the electronic system 2000.

The DRAM 2004 may be a buffer memory that is configured to relieve technical difficulties caused by a difference in speed between the semiconductor package 2003, which serves as a data storage device, and an external host. In an embodiment, the DRAM 2004 in the electronic system 2000 may serve as a cache memory and may be used as a storage space, which is used to temporarily store data during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b, which are spaced apart from each other. Each of the first and second semiconductor packages 2003a and 2003b may be a semiconductor package, in which a plurality of semiconductor chips 2200 are provided. Each of the first and second semiconductor packages 2003a and 2003b may include a package substrate 2100, the semiconductor chips 2200 on the package substrate 2100, adhesive layers 2300 under the semiconductor chips 2200, a connection structure 2400 electrically connecting the semiconductor chips 2200 to the package substrate 2100, and a molding layer 2500 provided on the package substrate 2100 to cover the semiconductor chips 2200 and the connection structure 2400.

The package substrate 2100 may be a printed circuit board including upper pads 2130. Each of the semiconductor chip 2200 may include an input/output pad 2210. The input/output pad 2210 may correspond to the input/output pad 1101 of FIG. 1B. Each of the semiconductor chips 2200 may include stacks 3210 and vertical structures 3220. Each of the semiconductor chips 2200 may include a three-dimensional semiconductor memory device, which will be described below.

In an embodiment, the connection structure 2400 may be a bonding wire electrically connecting the input/output pad 2210 to the upper pads 2130. Thus, in each of the first and second semiconductor packages 2003a and 2003b, the semiconductor chips 2200 may be electrically connected to each other in a bonding wire manner and may be electrically connected to the upper pads 2130 of the package substrate 2100. In other embodiments, the semiconductor chips 2200 in each of the first and second semiconductor packages 2003a and 2003b may be electrically connected to each other by a connection structure including through silicon vias (TSVs), not by the connection structure 2400 provided in the form of bonding wires.

In an embodiment, the controller 2002 and the semiconductor chips 2200 may be included in a single package. For example, the controller 2002 and the semiconductor chips 2200 may be mounted on a separate interposer substrate, which is prepared regardless of the main substrate 2001, and may be connected to each other through interconnection lines, which are provided in the interposer substrate.

FIGS. 1D and 1E are sectional views, which are taken along a line I-I′ of FIG. 1C to illustrate a semiconductor package including a three-dimensional semiconductor memory device according to an embodiment of the inventive concept.

Referring to FIGS. 1D and 1E, in the semiconductor package 2003, the package substrate 2100 may be a printed circuit board. The package substrate 2100 may include a package substrate body 2120, upper pads 2130, which are disposed on a top surface of the package substrate body 2120, lower pads 2125, which are disposed on or exposed through a bottom surface of the package substrate body 2120, and internal lines 2135, which are disposed in the package substrate body 2120 to electrically connect the upper pads 2130 to the lower pads 2125. The upper pads 2130 may be electrically connected to the connection structures 2400. The lower pads 2125 may be connected to the interconnection patterns 2005 of the main substrate 2001 of the electronic system 2000 through conductive connecting portions 2800, as shown in FIG. 1C.

Each of the semiconductor chips 2200 may include a semiconductor substrate 3010 and first and second structures 3100 and 3200, which are sequentially stacked on the semiconductor substrate 3010. The first structure 3100 may include a peripheral circuit region, in which peripheral interconnection lines 3110 are provided. The second structure 3200 may include a source structure 3205, a stack 3210, which is provided on the source structure 3205, vertical structures 3220 and separation structures 3230, which are provided to penetrate the stack 3210, bit lines 3240, which are electrically connected to the vertical structures 3220, and cell contact plugs 3235, which are electrically connected to the word lines WL of the stack 3210.

In the drawings, the stack 3210 is illustrated to have a stepwise structure, but the inventive concept is not limited to this example. For example, the stack 3210 may not have a stepwise structure, and the layers of the stack 3210 may have substantially the same length.

In the drawings, the second structure 3200 is illustrated as a single object, but the inventive concept is not limited to this example. For example, a third structure (not shown), which has the same or similar structure to the second structure 3200, may be provided on the second structure 3200. Here, the third structure may be electrically connected to the first structure 3100 through an additional penetration structure (not shown). Alternatively, two or more structures resembling or otherwise similar to the second structure 3200 may be further provided on the second structure 3200.

Each of the semiconductor chips 2200 may include penetration lines 3245, which are electrically connected to the peripheral interconnection lines 3110 of the first structure 3100 and are extended into the second structure 3200. The penetration lines 3245 may be disposed outside the stack 3210, and in an embodiment, at least one of the penetration lines 3245 may be disposed to penetrate the stack 3210. Each of the semiconductor chips 2200 may further include the input/output pads 2210 of FIG. 1C, which are electrically connected to the peripheral interconnection lines 3110 of the first structure 3100.

Referring to FIG. 1E, in a semiconductor package 2003A, each of semiconductor chips 2200a may include a semiconductor substrate 4010, a first structure 4100 on the semiconductor substrate 4010, and a second structure 4200, which is provided on the first structure 4100 and is bonded to the first structure 4100 in a wafer bonding manner.

The first structure 4100 may include a peripheral circuit region, in which a peripheral interconnection line 4110 and first junction structures 4150 are provided. The second structure 4200 may include a source structure 4205, a stack 4210, which is provided between the source structure 4205 and the first structure 4100, vertical structures 4220 and a separation structure 4230, which are provided to penetrate the stack 4210, and second junction structures 4250, which are electrically connected to the vertical structures 4220 and the word lines WL of the stack 4210. For example, the second junction structures 4250 may be electrically connected to the vertical structures 4220 and the word lines WL through bit lines 4240 and cell contact plugs 4235, which are respectively connected to the vertical structures 4220 and the word lines WL. The first junction structures 4150 of the first structure 4100 may be in contact with and bonded to the second junction structures 4250 of the second structure 4200. The bonding portions between the first and second junction structures 4150 and 4250 may be formed of, for example, copper (Cu).

In the drawings, the stack 4210 is illustrated to have a stepwise structure, but the inventive concept is not limited to this example. For example, the stack 4210 may not have a stepwise structure, and the layers of the stack 4210 may have substantially the same length.

In the drawings, the second structure 4200 is illustrated as a single object, but the inventive concept is not limited to this example. For example, a third structure (not shown), which has the same or similar structure to the second structure 4200, may be provided on the second structure 4200. Here, the third structure may be electrically connected to the first structure 4100 through an additional penetration structure (not shown). Alternatively, two or more structures resembling the second structure 4200 may be further provided on the second structure 4200.

Each of the semiconductor chips 2200a may further include the input/output pads 2210 of FIG. 1C, which are electrically connected to the peripheral interconnection lines 4110 of the first structure 4100.

The semiconductor chips 2200 of FIG. ID and the semiconductor chips 2200a of FIG. 1E may be electrically connected to each other through the connection structures 2400, which are provided in the form of bonding wires. However, in an embodiment, semiconductor chips (e.g., the semiconductor chips 2200 of FIG. 1D and the semiconductor chips 2200a of FIG. 1E), which are provided in each semiconductor package, may be electrically connected to each other through a connection structure, such as through-silicon vias (TSVs).

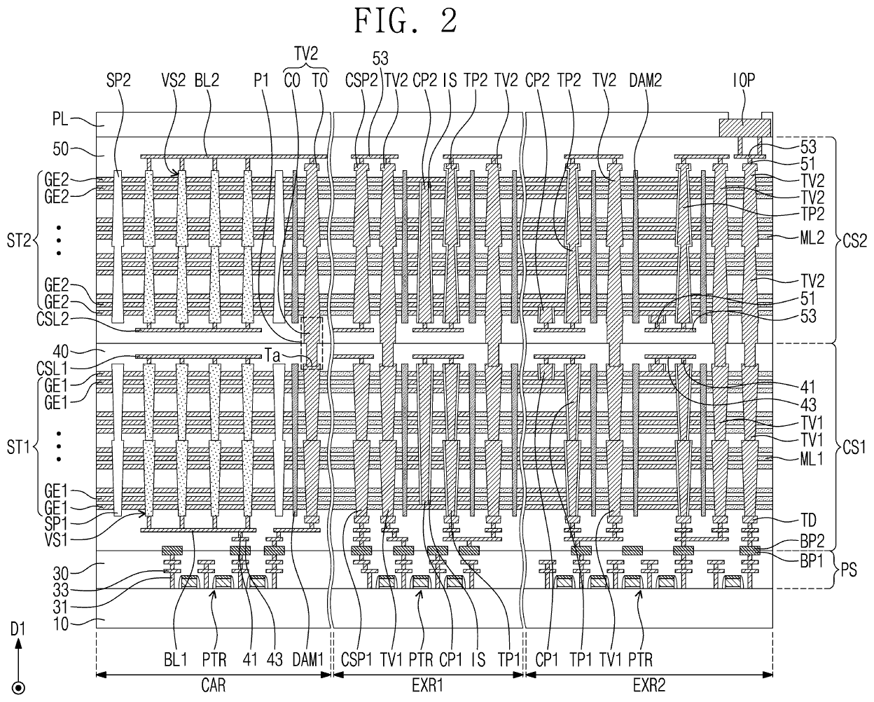

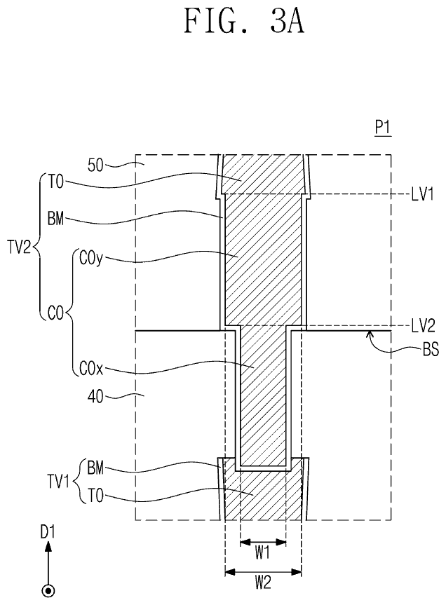

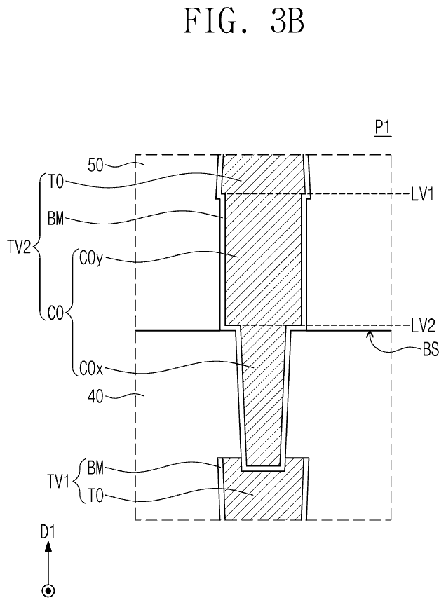

FIG. 2 is a sectional view illustrating a three-dimensional semiconductor memory device according to an embodiment of the inventive concept. FIGS. 3A and 3B are enlarged sectional views, each of which illustrates a portion ‘P1’ of FIG. 2.

Referring to FIG. 2, a three-dimensional semiconductor memory device may include a substrate 10, a peripheral circuit structure PS on the substrate 10, a first cell array structure CS1 on the peripheral circuit structure PS, and a second cell array structure CS2 on the first cell array structure CS1. The substrate 10 may correspond to the semiconductor substrate 3010 of FIG. 1D or the semiconductor substrate 4010 of FIG. 1E. The peripheral circuit structure PS may correspond to the first structure 3100 of FIG. 1D or the first structure 4100 of FIG. 1E. The first cell array structure CS1 may correspond to the second structure 3200 of FIG. 1D or the second structure 4200 of FIG. 1E. The second cell array structure CS2 may correspond to the third structure described with reference to FIG. 1D or FIG. 1E. In the drawings, two cell array structures are illustrated to be stacked on the peripheral circuit structure PS, but the inventive concept is not limited to this example. For example, three or more cell array structures may be provided on the peripheral circuit structure PS.

According to an embodiment of the inventive concept, the first and second cell array structures CS1 and CS2 may be bonded to the peripheral circuit structure PS, and in this case, the three-dimensional semiconductor memory device may have an increased cell capacity per a unit area. In addition, the peripheral circuit structure PS, the first cell array structure CS1, and the second cell array structure CS2 may be respectively fabricated, and then, they may be bonded to each other by an additional process. Thus, it may be possible to prevent peripheral transistors PTR, which will be described below, from being damaged by various thermal treatment processes. This may make it possible to improve the electrical and reliability characteristics of the three-dimensional semiconductor memory device.

The substrate 10 may be a silicon substrate, a silicon-germanium substrate, a germanium substrate, or a structure including a single-crystalline silicon substrate and a single-crystalline epitaxial layer grown therefrom. A top surface of the substrate 10 may be perpendicular to a first direction D1. The substrate 10 may include a cell array region CAR, a first extension region EXR1, and a second extension region EXR2.

The peripheral circuit structure PS on the substrate 10 may include peripheral transistors PTR, peripheral contact plugs 31, peripheral circuit interconnection lines 33, which are electrically connected to the peripheral transistors PTR through the peripheral contact plugs 31, first bonding pads BP1, which are electrically connected to the peripheral circuit interconnection lines 33, and a first insulating layer 30, which is provided to enclose them. The terms “enclose” or “surround” or “cover” or “fill” as may be used herein may not require completely enclosing or surrounding or covering or filling the described elements or layers, but may, for example, refer to partially enclosing or surrounding or covering or filling the described elements or layers, with one or more discontinuities or gaps therein. The peripheral transistors PTR may be provided on the active region of the substrate 10.

In an embodiment, the peripheral transistors PTR may constitute the row decoder 3, the page buffer 4, the CSL voltage controller 5, and the control logic 7 described with reference to FIGS. 1A and 1B.

The peripheral circuit interconnection lines 33 and the first bonding pads BP1 may be electrically connected to the peripheral transistors PTR via the peripheral contact plugs 31. Each of the peripheral transistors PTR may be, for example, an NMOS transistor or a PMOS transistor.

In an embodiment, the peripheral contact plugs 31 may have an increasing horizontal width, as a height in the first direction D1 increases. The peripheral contact plugs 31 and the peripheral circuit interconnection lines 33 may be formed of or include at least one of conductive materials (e.g., metallic materials).

The first insulating layer 30 may have a multi-layered structure including a plurality of insulating layers. In an embodiment, the first insulating layer 30 may be formed of or include at least one of silicon oxide, silicon nitride, silicon oxynitride, or low-k dielectric materials. In the present specification, the low-k dielectric material may be defined as a material having a dielectric constant lower than silicon oxide.

In an embodiment, the first bonding pad BP1 may be formed of or include copper (Cu). The first bonding pads BP1 may be in contact with, and electrically connected to, second bonding pads BP2, respectively.

The first cell array structure CS1 may be provided on the peripheral circuit structure PS. The first cell array structure CS1 may include a first stack ST1, a first vertical structure VS1, a first bit line BL1, a first common source line CSL1, a first common source plug CSP1, a first cell contact plug CP1, a first penetration plug TP1, first interconnection lines 43, first contact plugs 41, second bonding pads BP2, and a second insulating layer 40 covering them.

In an embodiment, each of the first interconnection line 43 and the first contact plug 41 may be formed of or include at least one of conductive materials (e.g., metallic materials). As the height in the first direction D1 increases, the first contact plug 41 may have an increasing horizontal width. In an embodiment, the second bonding pad BP2 may be formed of or include copper (Cu). The second insulating layer 40 may be formed of or include at least one of silicon oxide, silicon nitride, silicon oxynitride, or low-k dielectric materials.

The first stack ST1 may be provided on the first insulating layer 30. In an embodiment, a plurality of first stacks ST1 may be provided. As an example, when viewed in a plan view, the first stacks ST1 may be extended in a direction, which is parallel to the top surface of the substrate 10, and parallel to each other. Hereinafter, just one first stack ST1 will be described for brevity, but the others of the first stacks ST may also have similar or substantially the same features as described below.

The first stack ST1 may include first gate electrodes GE1, which are stacked in the first direction D1, first mold patterns ML1, which are provided at the same level as the first gate electrodes GE1, and first interlayer insulating layers (not shown), which are provided between the first gate electrodes GE1 and between the first mold patterns ML1. The first interlayer insulating layers may be portions of the second insulating layer 40.

The first gate electrodes GE1 may be continuously extended from the cell array region CAR to the second extension region EXR2. In an embodiment, the first gate electrodes GE1 may have substantially the same length in their extension direction. The first mold patterns ML1 may be extended in a horizontal direction, on each of the cell array region CAR, the first extension region EXR1, and the second extension region EXR2.

In an embodiment, the first gate electrode GE1 may be formed of or include at least one of doped semiconductor materials (e.g., doped silicon), metallic materials (e.g., tungsten, copper, aluminum, and molybdenum), conductive metal nitride materials (e.g., titanium nitride and tantalum nitride), or transition metals (e.g., titanium and tantalum). In an embodiment, the first interlayer insulating layers may be formed of or include at least one of silicon oxide, silicon nitride, silicon oxynitride, or low-k dielectric materials. The first mold patterns ML1 may include an insulating material (e.g., silicon nitride) having an etch selectivity with respect to the first interlayer insulating layers.

The first stack ST1 may be interposed between first separation patterns SP1, which are extended in a direction parallel to the top surface of the substrate 10. The first separation patterns SP1 may be formed of or include an insulating material (e.g., silicon oxide).

The first vertical structure VS1 may be provided on the cell array region CAR to penetrate the first stack ST1 in the first direction D1 and may be extended in the first direction D1. In detail, the first vertical structure VS1 may penetrate the first gate electrodes GE1 in the first direction D1. In an embodiment, a plurality of first vertical structures VS1 may be provided. When viewed in a plan view, the first vertical structures VS1 may be arranged to form a zigzag shape in a direction, which is parallel to the top surface of the substrate 10.

As the height in the first direction D1 increases, a portion of the first vertical structure VS1 may have an increasing horizontal width. In detail, the first vertical structure VS1 may include a first portion, which is provided to penetrate a lower portion of the first stack ST1, and an second portion, which is provided to penetrate an upper portion of the first stack ST1. Each of the first and second portions of the first vertical structure VS1 may be provided to have an increasing horizontal width, as the height in the first direction D1 increases. The first and second portions of the first vertical structure VS1 may define a step difference or form a stepwise structure near a boundary therebetween, but the inventive concept is not limited to this example.

The first vertical structure VS1 may be composed of a plurality of thin films. In an embodiment, the first vertical structure VS1 may include a semiconductor pattern (not shown), which includes a semiconductor material (e.g., silicon (Si) or germanium (Ge)), and a charge storing layer (not shown), a blocking insulating layer (not shown), and a tunnel insulating layer (not shown), which are used as a data storing layer of a NAND FLASH memory device. In an embodiment, the charge storing layer may be enclosed by the blocking insulating layer and the tunnel insulating layer and may be a trap insulating layer, a floating gate electrode, or an insulating layer with conductive nanodots.

The first bit line BL1 on the cell array region CAR may be interposed between the peripheral circuit structure PS and the first stack ST1, but the inventive concept is not limited to this example. The first bit line BL1 on the cell array region CAR may be provided on the top surface of the first stack ST1. In an embodiment, the first bit line BL1 may be formed of or include at least one of conductive materials (e.g., metallic materials).

In an embodiment, a plurality of first bit lines BL1 may be provided. Each of the first bit lines BL1 may be electrically connected to the first vertical structures VS1, which are arranged in the extension direction of the bit line, through the first contact plugs 41. The first bit lines BL1 may be electrically connected to the second bonding pads BP2 through the first interconnection lines 43 and the first contact plugs 41. As a result, the first bit line BL1 may be electrically connected to the peripheral circuit structure PS through the peripheral elements described above.

In an embodiment, the first common source line CSL1 may be provided on the first stack ST1, but the inventive concept is not limited to this example. For example, the first common source line CSL1 may be interposed between the peripheral circuit structure PS and the first stack ST1. In an embodiment, the first common source line CSL1 may be formed of or include at least one of doped semiconductor materials (e.g., doped silicon), metallic materials (e.g., tungsten, molybdenum, nickel, copper, and aluminum), conductive metal nitride materials (e.g., titanium nitride and tantalum nitride), or transition metals (e.g., titanium and tantalum).

The first common source line CSL1 may be electrically connected to the first vertical structures VS1 through the first contact plugs 41. The first common source line CSL1 may be extended from the cell array region CAR to the first extension region EXR1.

The first common source plug CSP1 may be provided on the first extension region EXR1. The first common source plug CSP1 may penetrate the first mold pattern ML1 in the first direction D1. A penetration pad TD may be provided below the first common source plug CSP1. The first common source plug CSP1 and the penetration pad TD may be formed of or include at least one of metallic materials (e.g., Ti, Mo, W, Cu, Al, Ta, Ru, Ir, Co, Pt, Au, and Ag) or metal nitride materials (e.g., nitrides of Ti, Mo, W, Cu, Al, Ta, Ru, Ir, and Co).

The first common source plug CSP1 may be electrically connected to the first common source line CSL1 through the first contact plug 41. Accordingly, the first common source line CSL1 may be electrically connected to the second bonding pad BP2 through the first common source plug CSP1, the penetration pad TD, the first contact plug 41, and the first interconnection lines 43. As a result, the first common source line CSL1 may be electrically connected to the peripheral circuit structure PS through the peripheral elements described above.

The first cell contact plug CP1 and the first penetration plug TP1 may be provided on each of the first and second extension regions EXR1 and EXR2 to penetrate the first gate electrodes GE1 in the first direction D1. The first cell contact plug CP1 and the first penetration plug TP1 may be formed of or include at least one of metallic materials (e.g., Ti, Mo, W, Cu, Al, Ta, Ru, Ir, Co, Pt, Au, and Ag) or metal nitride materials (e.g., nitrides of Ti, Mo, W, Cu, Al, Ta, Ru, Ir, and Co). The first cell contact plug CP1 may be electrically connected to the first penetration plug TP1 through the first contact plug 41 and the first interconnection line 43. The first penetration plug TP1 may be electrically connected to the second bonding pad BP2 through the penetration pad TD, the first contact plugs 41, and the first interconnection line 43. As a result, the first cell contact plug CP1 may be electrically connected to the peripheral circuit structure PS through the peripheral elements described above.

In an embodiment, a plurality of first cell contact plugs CP1 may be provided. The first cell contact plugs CP1 may be provided on the first extension region EXR1 and the second extension region EXR2. Each of the first cell contact plugs CP1 may penetrate at least one of the first gate electrodes GE1 and may be in contact with, and electrically connected to, a corresponding one of the first gate electrodes GE1. The first cell contact plugs CP1 may have different vertical lengths and may have bottom surfaces that are formed at different vertical levels relative to the substrate 10. In an embodiment, as a distance from the cell array region CAR increases, the vertical lengths of the first cell contact plugs CP1 may increase or decrease.

An insulating spacer IS may be interposed between the first cell contact plug CP1 and the first gate electrodes GE1 and between the first penetration plug TP1 and the first gate electrodes GE1. In an embodiment, the insulating spacer IS may be formed of or include at least one of silicon oxide, silicon nitride, silicon oxynitride, or low-k dielectric materials.

First dams DAM1 may be provided on the cell array region CAR and the first and second extension regions EXR1 and EXR2 to penetrate the first stack ST1 in the first direction D1. Each of the first dams DAM1 may be interposed between the first gate electrodes GE1 and the first mold patterns ML1 and may be extended in the first direction D1, between the first gate electrodes GE1 and the first mold patterns ML1. The first gate electrodes GE1 may be spaced apart from the first mold patterns ML1 by the first dams DAM1. In an embodiment, the first dam DAM1 may include an insulating material.

A first penetration via TV1 may be provided on each of the cell array region CAR, the first extension region EXR1, and the second extension region EXR2 to penetrate the first stack ST1 in the first direction D1. For example, the first penetration via TV1 may penetrate the first mold pattern ML1 in the first direction D1. The first penetration via TV1 may be enclosed by the first dam DAM1. The first penetration via TV1 may be provided to form a stepwise structure (e.g., defining a step difference along a sidewall between upper and lower portions thereof), similar to the first vertical structure VS1. For example, as the height in the first direction D1 increases relative to the substrate 10, a width of a portion of the first penetration via TV1 may increase in a direction parallel to the top surface of the substrate 10.

In an embodiment, a plurality of first penetration vias TV1 may be provided. Each of the first penetration vias TV1 may be electrically connected to the second bonding pad BP2 through the penetration pad TD, the first contact plugs 41, and the first interconnection lines 43. As a result, the first penetration via TV1 may be electrically connected to the peripheral circuit structure PS through the peripheral elements described above.

Referring to FIGS. 2 and 3, the first penetration via TV1 may include a penetration portion TO and a barrier pattern BM enclosing a side surface of the penetration portion TO. As an example, the penetration portion TO may be formed of or include at least one of metallic materials (e.g., Ti, Mo, W, Cu, Al, Ta, Ru, Ir, Co, Pt, Au, and Ag). The barrier pattern BM may be formed of or include at least one of metal nitride materials (e.g., nitride materials of Ti, Mo, W, Cu, Al, Ta, Ru, Ir, and Co).

Referring back to FIG. 2, the second cell array structure CS2 may be provided on the first cell array structure CS1. The second cell array structure CS2 may include a second stack ST2, a second vertical structure VS2, a second bit line BL2, a second common source line CSL2, a second common source plug CSP2, a second cell contact plug CP2, a second penetration plug TP2, second interconnection lines 53, second contact plugs 51, and a third insulating layer 50 covering them.

The second interconnection lines 53, the second contact plugs 51 and the third insulating layer 50 may be provided to have similar or substantially the same features as the first interconnection lines 43, the first contact plugs 41, and the second insulating layer 40, respectively. As the height in the first direction D1 increases, the second contact plugs 51 may have a decreasing horizontal width.

The second stack ST2 may be provided on the second insulating layer 40. The second stack ST2 may be provided to have similar or substantially the same features as the first stack ST1.

The second stack ST2 may include second gate electrodes GE2, which are stacked in the first direction D1, second mold patterns ML2, which are provided at the same level (relative to the substrate 10) as the second gate electrodes GE2, and second interlayer insulating layers (not shown), which are provided between the second gate electrodes GE2 and between the second mold patterns ML2. The second interlayer insulating layers may be portions of the third insulating layer 50. The second gate electrodes GE2, the second mold patterns ML2, and the second interlayer insulating layers may be provided to have similar or substantially the same features as the first gate electrodes GE1, the first mold patterns ML1, and the first interlayer insulating layers, respectively.

The second stack ST2 may be interposed between second separation patterns SP2, which are extended in a direction parallel to the top surface of the substrate 10 and parallel to be each other. The second separation patterns SP2 may be provided to have similar or substantially the same features as the first separation patterns SP1.

The second vertical structure VS2 may be provided on the cell array region CAR to penetrate the second stack ST2 in the first direction D1 and may be extended in the first direction D1. In detail, the second vertical structure VS2 may penetrate the second gate electrodes GE2 in the first direction D1. The second vertical structure VS2 may be provided to have similar or substantially the same features as the first vertical structure VS1. The second vertical structure VS2 may be spaced apart from the first vertical structure VS1 in the first direction D1. The first and second vertical structures VS1 and VS2 may be provided symmetrically with respect to a horizontal plane therebetween (such as an interface BS between the first cell array structure CS1 and the second cell array structure CS2). For example, as the height in the first direction D1 increases relative to the substrate 10, a portion of the first vertical structure VS1 may have an increasing horizontal width, and a portion of the second vertical structure VS2 may have a decreasing horizontal width.

As an example, the second bit line BL2 may be provided on the second stack ST2, on the cell array region CAR, but the inventive concept is not limited to this example. As another example, the second bit line BL2 may be provided between the first stack ST1 and the second stack ST2, on the cell array region CAR. In an embodiment, the second bit line BL2 may be formed of or include the same material as the first bit line BL1.

In an embodiment, a plurality of second bit lines BL2 may be provided. Each of the second bit lines BL2 may be electrically connected to the second vertical structures VS2, which are arranged in the extension direction of the second bit line BL2, through the second contact plugs 51.

In an embodiment, the second common source line CSL2 may be interposed between the first stack ST1 and the second stack ST2, but the inventive concept is not limited to this example. For example, the second common source line CSL2 may be provided on the second stack ST2. The second common source line CSL2 may be formed of or include the same material as the first common source line CSL1.

The second common source line CSL2 may be electrically connected to the second vertical structures VS2 through the second contact plugs 51. The second common source line CSL2 may be extended from the cell array region CAR to the first extension region EXR1.

The second common source plug CSP2 may be provided on the first extension region EXR1 to penetrate the second mold pattern ML2 in the first direction D1. A portion of the second common source plug CSP2 (e.g., located at a level higher than the second vertical structure VS2) may have a similar (or mirrored) shape of the penetration pad TD with respect to the horizontal plane. As an example, the second common source plug CSP2 may include the same material as the first common source plug CSP1. The second common source plug CSP2 may be electrically connected to the second common source line CSL2 through the second contact plug 51.

The second cell contact plug CP2 and the second penetration plug TP2 may be provided on each of the first and second extension regions EXR1 and EXR2 to penetrate the second gate electrodes GE2 in the first direction D1. In an embodiment, the second cell contact plug CP2 and the second penetration plug TP2 may be formed of or include the same materials as the first cell contact plug CP1 and the first penetration plug TP1, respectively. The second cell contact plug CP2 may be electrically connected to the second penetration plug TP2 through the second contact plugs 51 and the second interconnection line 53.

In an embodiment, a plurality of second cell contact plugs CP2 may be provided. Each of the second cell contact plugs CP2 may penetrate at least one of the second gate electrodes GE2 and may be in contact with, and electrically connected to, a corresponding one of the second gate electrodes GE2. The vertical lengths of the second cell contact plugs CP2 may have substantially the same features as the vertical lengths of the first cell contact plugs CP1.

The insulating spacer IS may be interposed between the second cell contact plug CP2 and the second gate electrodes GE2 and between the second penetration plug TP2 and the second gate electrodes GE2.

Second dams DAM2 may be provided on each of the cell array region CAR and the first and second extension regions EXR1 and EXR2 to penetrate the second stack ST2 in the first direction D1. The second dams DAM2 may be respectively interposed between the second gate electrodes GE2 and the second mold patterns ML2 and may be extended in the first direction D1. The second gate electrodes GE2 may be spaced apart from the second mold patterns ML2 by the second dams DAM2. In an embodiment, the second dam DAM2 may include an insulating material.

A second penetration via TV2 may be provided on each of the cell array region CAR, the first extension region EXR1, and the second extension region EXR2 to penetrate the second stack ST2 in the first direction D1. In an embodiment, the second penetration via TV2 may be provided to penetrate the second mold pattern ML2 in the first direction D1. The second penetration via TV2 may be enclosed by the second dam DAM2. The second penetration via TV2 may be provided to form a stepwise structure (e.g., defining a step difference along a sidewall between upper and lower portions thereof), similar to the second vertical structure VS2. In an embodiment, as the height in the first direction D1 increases, a portion of the second penetration via TV2 may have a decreasing width in a direction parallel to the top surface of the substrate 10. A vertical length of the second penetration via TV2 may be larger than a vertical length of the second vertical structure VS2 in the first direction D1.

The second penetration via TV2 may be provided on a top surface Ta of the first penetration via TV1. The second penetration via TV2 may be in contact with the top surface Ta of the first penetration via TV1 and may be continuously extended from the top surface Ta of the first penetration via TV1 into the second cell array structure CS2 in the first direction D1. The second penetration via TV2 may be electrically connected to the first penetration via TV1. The second penetration via TV2 may be vertically overlapped with the first penetration via TV1 in the direction D1. Components or layers described with reference to “overlap” in a particular direction may be at least partially obstructed by one another when viewed along a line extending in the particular direction or in a plane perpendicular to the particular direction. A portion of the second penetration via TV2 may be placed or may be present in the first cell array structure CS1.

In an embodiment, a plurality of second penetration vias TV2 may be provided. At least one of the second penetration vias TV2 may be electrically connected to the second bit line BL2 through the second interconnection line 53 and the second contact plug 51. At least one of the second penetration vias TV2 may be electrically connected to the second common source line CSL2 through the second interconnection line 53, the second contact plug 51, and the second common source plug CSP2. At least one of the second penetration vias TV2 may be electrically connected to the second cell contact plug CP2 through the second interconnection line 53, the second contact plug 51, and the second penetration plug TP2. At least one of the second penetration vias TV2 may be electrically connected to an input/output pad IOP through the second interconnection line 53 and the second contact plug 51.

Each of the second penetration vias TV2 may be provided on a top surface of a corresponding one of the first penetration vias TV1. Each of the second penetration vias TV2 may be electrically connected to a corresponding one of the first penetration vias TV1. Accordingly, each of the second bit line BL2, the second common source line CSL2, the second cell contact plug CP2, and the input/output pad IOP may be electrically connected to the peripheral circuit structure PS through the first and second penetration vias TV1 and TV2.

According to an embodiment of the inventive concept, the second penetration via TV2 may be in contact with the top surface Ta of the first penetration via TV1 in the first cell array structure CS1 and may be extended from the top surface Ta of the first penetration via TV1 into the second cell array structure CS2 in the first direction D1. That is, the second penetration via TV2 may continuously extend from the second cell array structure CS2 and into the first cell array structure CS1 beyond the interface BS therebetween, to directly contact a top surface Ta of the first penetration via TV1, which is below the interface between the cell array structures CS1 and CS2. Although additional or distinct elements, such as the first and second bonding pads BP1 and BP2, are not provided, each of the second bit line BL2, the second common source line CSL2, the second cell contact plug CP2, and the input/output pad IOP may be electrically connected to the peripheral circuit structure PS through the first and second penetration vias TV1 and TV2, which are in direct contact with each other free of bonding pads therebetween. As a result, it may be possible to omit a process of forming the additional elements, such as the first and second bonding pads BP1 and BP2, and to simplify the fabrication process. This may enable productive fabrication of the three-dimensional semiconductor memory device.

In addition, since the first and second penetration vias TV1 and TV2 are directly bonded to each other without additional or distinct intervening elements (such as the first and second bonding pads BP1 and BP2) therebetween, the electrical resistance between the first and second penetration vias TV1 and TV2 may be reduced. Thus, the electrical characteristics of the three-dimensional semiconductor memory device may be improved.

Referring to FIGS. 3A and 3B, the second penetration via TV2 may include the penetration portion TO, a connecting portion CO, which is provided between the penetration portion TO and the first penetration via TV1, and the barrier pattern BM, which is provided to enclose the penetration portion TO and the connecting portion CO. The penetration portion TO and the connecting portion CO may be distinguishable from each other at a first level LV1. In an embodiment, the first level LV1 may be defined as a level where the penetration portion TO and the connecting portion CO are connected to each other to form a stepwise structure or step difference. In an embodiment, the penetration portion TO and the connecting portion CO may be formed of or include at least one of metallic materials (e.g., Ti, Mo, W, Cu, Al, Ta, Ru, Ir, Co, Pt, Au, and Ag). The penetration portion TO and the connecting portion CO may be provided to form a single object or unitary member. The barrier pattern BM may be formed of or include at least one of metal nitride materials (e.g., nitride materials of Ti, Mo, W, Cu, Al, Ta, Ru, Ir, and Co).

The penetration portion TO may be a portion of the second penetration via TV2 penetrating the second stack ST2. As the height in the first direction D1 increases (relative to the substrate 10), a portion of the penetration portion TO may have a decreasing width in a direction parallel to the top surface of the substrate 10.

The connecting portion CO may be placed between the first stack ST1 and the second stack ST2. A side surface or sidewall of the connecting portion CO may have a stepwise structure or step difference at a second level LV2 between upper and lower portions thereof. As described above, the second level LV2 may be defined as a level, at which the side surface of the connecting portion CO has the stepwise structure or step difference. The second level LV2 may be placed at a level higher than a bonding surface BS (i.e., the interface between the second cell array structure CS2 and the first cell array structure CS1) relative to the substrate 10. The connecting portion CO may include an upper portion COy, which is provided at a level higher than the second level LV2, and a lower portion COx, which is provided at a level lower than the second level LV2. The lower portion COx of the connecting portion CO may be placed in an upper portion of the first cell array structure CS1. The upper portion COy of the connecting portion CO may be placed in a lower portion of the second cell array structure CS2. When measured in a direction parallel to the top surface of the substrate 10, a width W2 of the upper portion COy of the connecting portion CO may be larger than a width W1 of the lower portion COx of the connecting portion CO, defining the step difference.

The barrier pattern BM may cover the side surface of the connecting portion CO and may be continuously extended, in the first direction D1, to a region between the penetration portion TO and the second stack ST2. The barrier pattern BM may be interposed between the connecting portion CO and the first penetration via TV1. In an embodiment, the barrier pattern BM may be in contact with each of the connecting portion CO and the first penetration via TV1.

Referring back to FIG. 2, a protection layer PL may be provided on the second cell array structure CS2. The protection layer PL may be a single layer, which is made of a single material, or a composite layer including two or more materials. In an embodiment, the protection layer PL may have a structure, in which silicon oxide, silicon nitride, and a polyimide-based material (e.g., photo-sensitive polyimide (PSPI)) are sequentially stacked, but the inventive concept is not limited to this example.

The input/output pad IOP may be provided in the protection layer PL. A portion of the input/output pad IOP may be exposed externally or to the outside through an opening in the protection layer PL. In an embodiment, the input/output pad IOP may be formed of or include at least one of conductive materials (e.g., metallic materials).

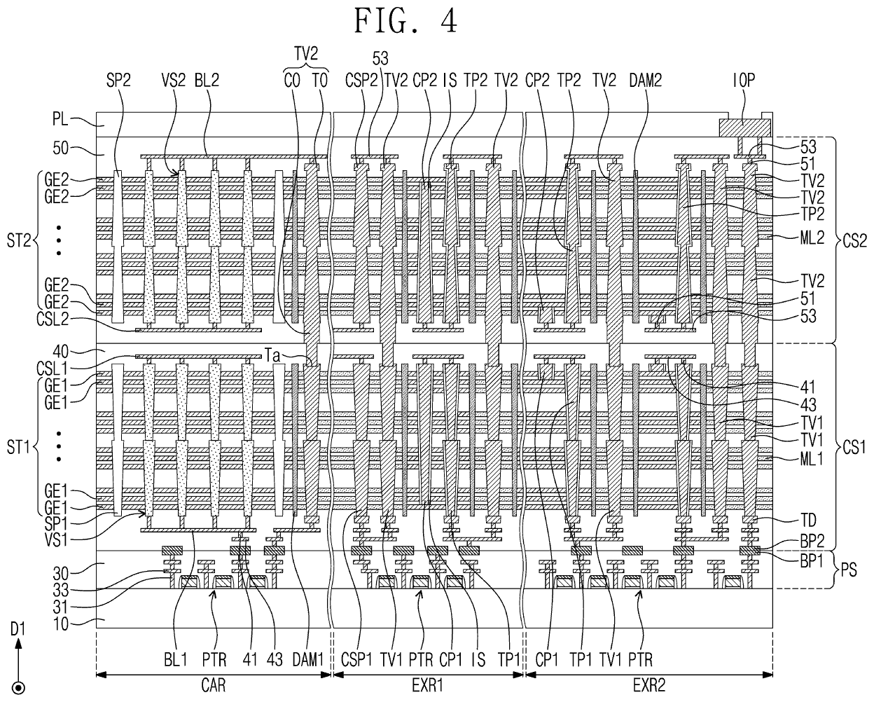

Hereinafter, various examples of the three-dimensional semiconductor memory device will be described in more detail with reference to FIGS. 4 to 9. For concise description, a previously described element may be identified by the same reference number without repeating an overlapping description thereof.

FIG. 4 is a sectional view illustrating a three-dimensional semiconductor memory device according to an embodiment of the inventive concept.

Referring to FIG. 4, one of the peripheral transistors PTR may be used to control a voltage applied to each of the first and second common source lines CSL1 and CSL2.

In detail, the first common source plug CSP1 and the first penetration via TV1, which are adjacent to each other, may be electrically connected to one of the second bonding pads BP2 through the first interconnection line 43 and the first contact plug 41. The second common source plug CSP2 may be electrically connected to the first penetration via TV1, which is adjacent to the first common source plug CSP1, through the second penetration via TV2. As described above, the first common source line CSL1 may be electrically connected to the first common source plug CSP1, and the second common source line CSL2 may be electrically connected to the second common source plug CSP2. In other words, the first and second common source lines CSL1 and CSL2 may be electrically connected to one of the second bonding pads BP2. Accordingly, the voltage, which is applied to each of the first and second common source lines CSL1 and CSL2, may be controlled through one of the peripheral transistors PTR, which is electrically connected to one of the second bonding pads BP2.

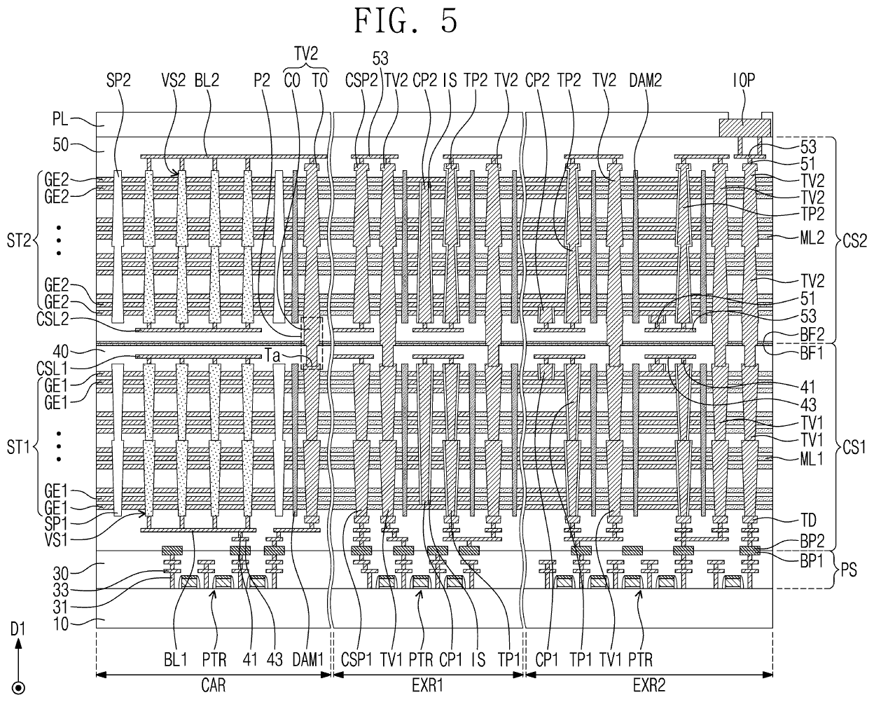

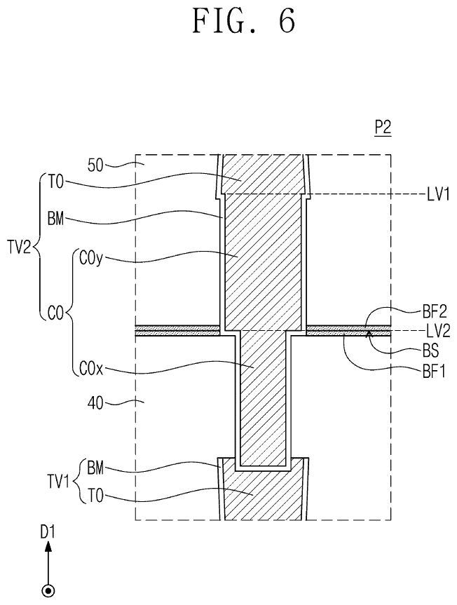

FIG. 5 is a sectional view illustrating a three-dimensional semiconductor memory device according to an embodiment of the inventive concept. FIG. 6 is an enlarged sectional view illustrating a portion ‘P2’ of FIG. 5.

Referring to FIGS. 5 and 6, a first buffer layer BF1 and a second buffer layer BF2 may be provided near the bonding surface BS. In detail, the first buffer layer BF1 may be provided in an upper portion of the first cell array structure CS1, and the second buffer layer BF2 may be provided in a lower portion of the second cell array structure CS2. The second buffer layer BF2 may be provided on the first buffer layer BF1. A top surface of the first buffer layer BF1 and a bottom surface of the second buffer layer BF2 may be in contact with each other. The contact surface between the top surface of the first buffer layer BF1 and the bottom surface of the second buffer layer BF2 may be defined as the bonding surface BS. In an embodiment, each of the first and second buffer layers BF1 and BF2 may be formed of or include SiCN.

The connecting portion CO of the second penetration via TV2 may penetrate the first and second buffer layers BF1 and BF2 in the first direction D1. The connecting portion CO of the second penetration via TV2 may have a stepwise structure or step difference at a level lower than the bonding surface BS. In an embodiment, the connecting portion CO of the second penetration via TV2 may have the stepwise structure or step difference at the same level as the bottom surface of the first buffer layer BF1.

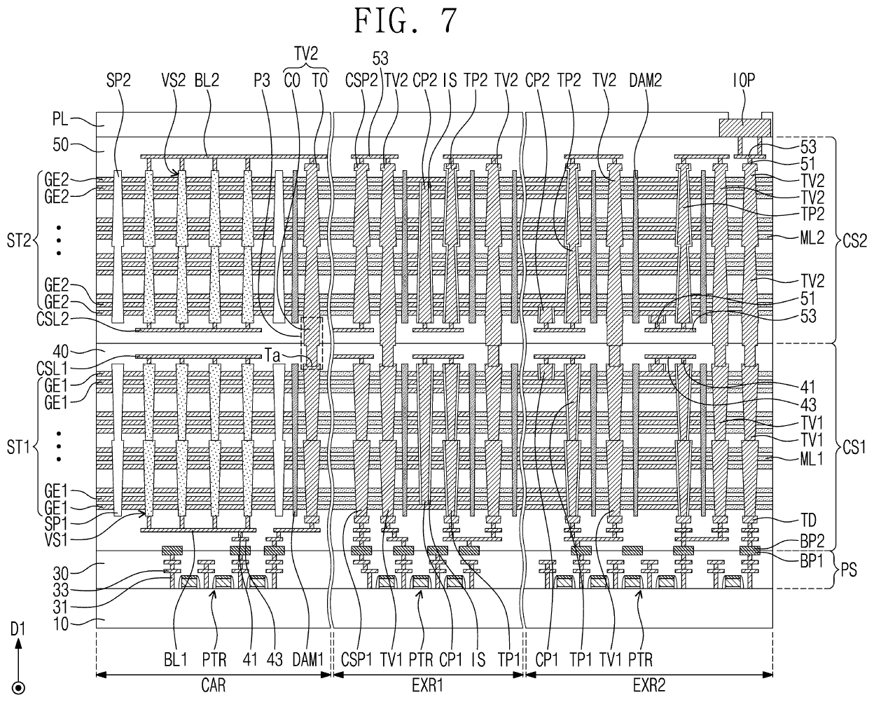

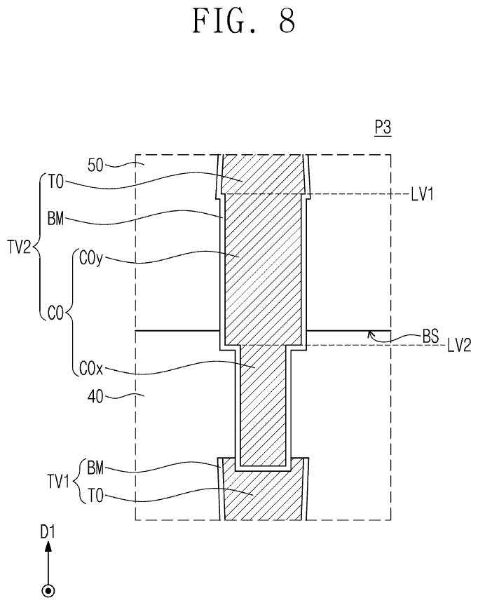

FIG. 7 is a sectional view illustrating a three-dimensional semiconductor memory device according to an embodiment of the inventive concept. FIG. 8 is an enlarged sectional view illustrating a portion ‘P3’ of FIG. 7.

Referring to FIGS. 7 and 8, the first and second cell array structures CS1 and CS2 may be in direct contact with each other, without the first and second buffer layers BF1 and BF2 described with reference to FIGS. 5 and 6. The upper portion COy of the connecting portion CO of the second penetration via TV2 may be partially placed in the first cell array structure CS1. In other words, the connecting portion CO of the second penetration via TV2 may have a stepwise structure at a level lower than the bonding surface BS.

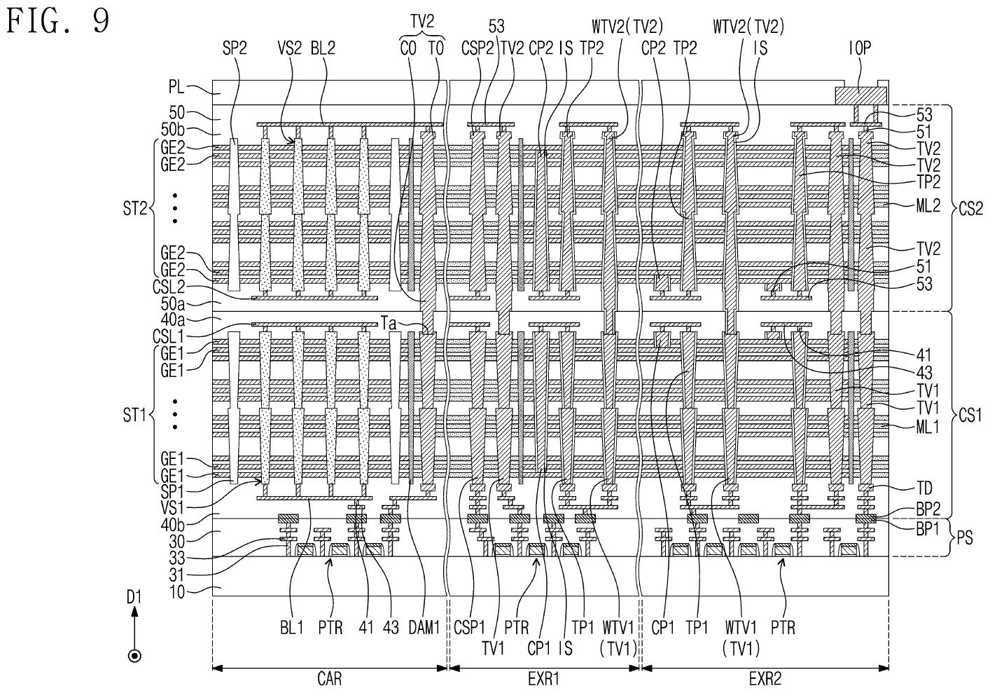

FIG. 9 is a sectional view illustrating a three-dimensional semiconductor memory device according to an embodiment of the inventive concept.

Referring to FIG. 9, the first penetration via TV1 may include a first word line penetration via WTV1, which is electrically connected to the first penetration plug TP1. The second penetration via TV2 may include a second word line penetration via WTV2, which is electrically connected to the second penetration plug TP2. The structural relationship (e.g., placement and connection) between the first and second word line penetration vias WTV1 and WTV2 may be the same or similar to that between the first and second penetration vias TV1 and TV2 described with reference to FIG. 2.

Unlike the embodiment described with reference to FIG. 2, the first dam DAM1 may not be interposed between the first word line penetration via WTV1 and the first penetration plug TP1, and the second dam DAM2 may not be interposed between the second word line penetration via WTV2 and the second penetration plug TP2. The first word line penetration via WTV1 may penetrate the first gate electrodes GE1 in the first direction D1, and the second word line penetration via WTV2 may penetrate the second gate electrodes GE2 in the first direction D1. Here, to electrically disconnect the first gate electrodes GE1 from the first word line penetration via WTV1, the insulating spacer IS may be interposed between the first gate electrodes GE1 and the first word line penetration via WTV1. Similarly, to electrically disconnect the second gate electrodes GE2 from the second word line penetration via WTV2, the insulating spacer IS may be interposed between the second gate electrodes GE2 and the second word line penetration via WTV2.

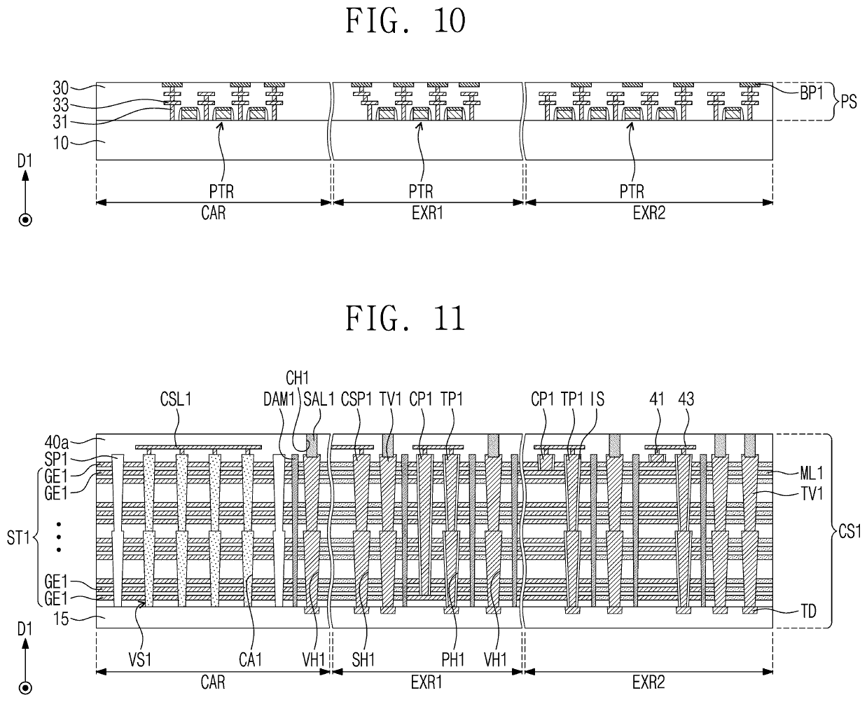

Hereinafter, a method of fabricating a three-dimensional semiconductor memory device, according to an embodiment of the inventive concept, will be described in more detail with reference to FIGS. 10 to 19. For concise description, a previously described element may be identified by the same reference number without repeating an overlapping description thereof.

FIGS. 10 to 15 are sectional views illustrating a method of fabricating a three-dimensional semiconductor memory device, according to an embodiment of the inventive concept.

Referring to FIG. 10, the peripheral circuit structure PS may be formed on the substrate 10. The formation of the peripheral circuit structure PS may include forming the peripheral transistors PTR on the active region of the substrate 10 and forming the peripheral contact plugs 31, the peripheral circuit interconnection lines 33, the first bonding pads BP1, which are electrically connected to the peripheral transistors PTR, and the first insulating layer 30 covering them. The substrate 10 will be called the first substrate 10, in the description of the fabrication method.

Top surfaces of the first bonding pads BP1 may be substantially coplanar with a top surface of the first insulating layer 30. In an embodiment, a planarization process may be performed to form the substantially coplanar surfaces.

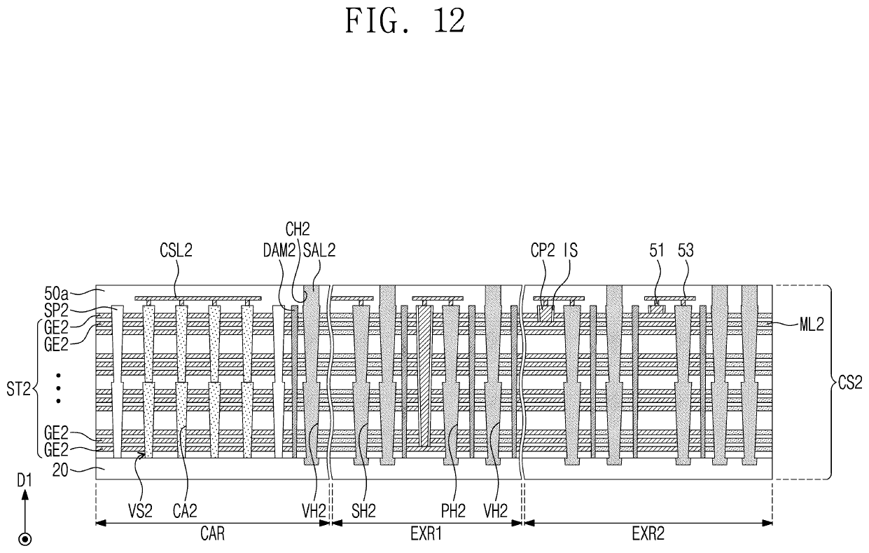

Referring to FIG. 11, penetration pads TD may be formed in an upper portion of a second substrate 15. The first stack ST1, in which the first mold patterns ML1 and the first interlayer insulating layers are alternatingly stacked in the first direction D1, may be formed on the second substrate 15. In an embodiment, the second substrate 15 may include a semiconductor substrate.

First channel holes CA1, first penetration via holes VH1, a first source via hole SH1, and first plug via holes PHI may be formed to penetrate the first stack ST1 in the first direction D1. In an embodiment, the first channel holes CA1, the first penetration via holes VH1, the first source via hole SH1, and the first plug via holes PHI may be formed at the same time, but the inventive concept is not limited to this example.

The first vertical structures VS1 may be formed in the first channel holes CA1. As an example, the formation of the first vertical structure VS1 may include sequentially forming a blocking insulating layer (not shown), a charge storing layer (not shown), a tunnel insulating layer (not shown), and a semiconductor pattern (not shown) in the first channel hole CA1.

The first dams DAM1 may be formed to penetrate the first stack ST1 in the first direction D1.

Trenches may be formed to penetrate the first interlayer insulating layers and the first mold patterns ML1 in the first direction D1 and to expose the second substrate 15. The first gate electrodes GE1 may be formed between the first interlayer insulating layers by replacing the first mold patterns ML1, which are exposed through the trenches, with a conductive material. The first mold patterns ML1, which are enclosed by the first dams DAM1, may be left in place without being replaced by the first gate electrodes GE1. The first separation patterns SP1 may be formed to fill inner regions of the trenches.

The first penetration vias TV1 may be formed to fill the first penetration via holes VH1. The first common source plug CSP1 may be formed to fill the first source via hole SH1. The insulating spacer IS may conformally cover inner surfaces of the first plug via holes PH1. Thereafter, the first penetration plugs TP1 may be formed to fill remaining spaces of the first plug via holes PH1.

At least one of the first cell contact plugs CP1 may be formed to penetrate at least one of the first gate electrodes GE1 in the first direction D1 and to be in contact with one of the first gate electrodes GE1. One of the first cell contact plugs CP1 may be formed to be in contact with the uppermost one of the first gate electrodes GE1. Before the formation of the first cell contact plugs CP1, the insulating spacer IS may be formed in regions where the first cell contact plugs CP1 will be formed.

A first portion 40a of the second insulating layer 40 (e.g., see FIG. 2) may be formed to fully cover the first stack ST1.

The first contact plugs 41 may be formed on top surfaces of the first vertical structures VS1, the first common source plug CSP1, the first cell contact plugs CP1, and the first penetration plugs TP1, respectively.

The first common source line CSL1 may be formed to cover top surfaces of the first contact plugs 41, which are in contact with the top surfaces of the first vertical structures VS1, and may be extended to a region on the top surface of the first contact plug 41, which is in contact with the top surface of the first common source plug CSP1.

Each of the first interconnection lines 43 may be formed to cover the top surface of the first contact plug 41, which is in contact with the top surface of the first cell contact plug CP1, and may be extended to a region on a top surface of the first penetration plug TP1.

The first portion 40a of the second insulating layer 40 (e.g., see FIG. 2) may be formed through two or more distinct steps. The first portion 40a of the second insulating layer 40 (e.g., see FIG. 2) may be formed at various points in time, taking into account when the steps of forming the first common source line CSL1, the first contact plugs 41, and the first interconnection lines 43 are performed.

First connection holes CH1 may be formed on the first penetration vias TV1. The first connection holes CH1 may be vertically overlapped with the first penetration via holes VH1, respectively. First sacrificial layers SAL1 may be formed to fill the first connection holes CH1. In an embodiment, the first sacrificial layers SAL1 may be formed of or include at least one of C, Poly Si, W, or TiN. In an embodiment, a planarization process may be further performed on upper portions of the first sacrificial layers SAL1, during the formation of the first sacrificial layers SAL1. In this case, the first sacrificial layers SAL1 may be formed to have top surfaces that are substantially coplanar with the top surface of the first portion 40a of the second insulating layer 40 (e.g., see FIG. 2).

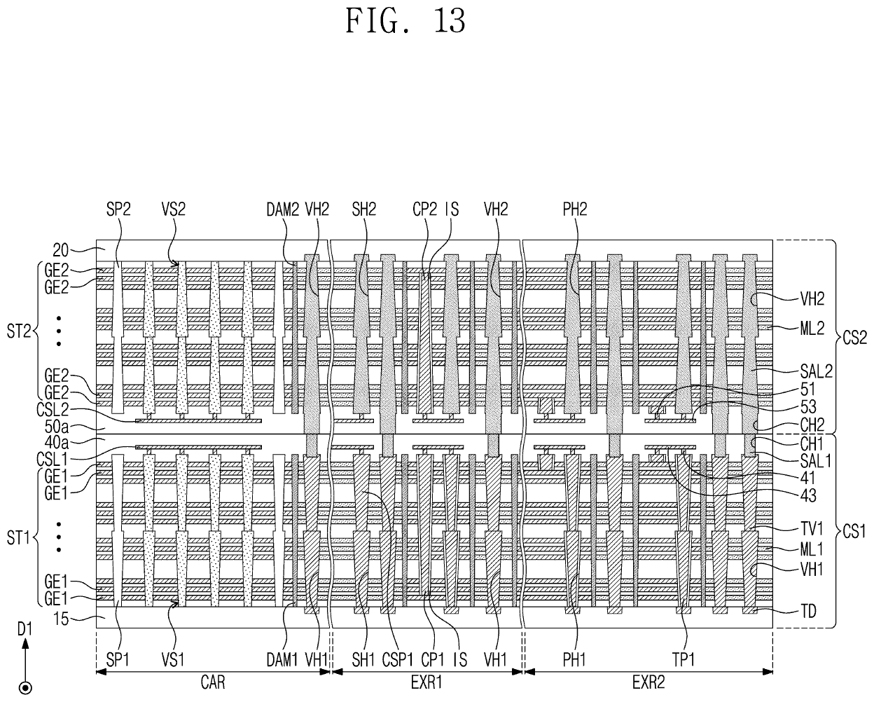

Referring to FIG. 12, the second stack ST2, in which the second mold patterns ML2 and the second interlayer insulating layers are alternatingly stacked in the first direction D1, may be formed on a third substrate 20. In an embodiment, the third substrate 20 may include a semiconductor substrate.

Second channel holes CA2, second penetration via holes VH2, a second source via hole SH2, and second plug via holes PH2 may be formed to penetrate the second stack ST2 in the first direction D1.

The second vertical structures VS2 may be formed in the second channel holes CA2. The formation of the second vertical structures VS2 may be performed using the same method as that for the first vertical structures VS1 described with reference to FIG. 11.

The second dams DAM2 may be formed to penetrate the second stack ST2 in the first direction D1.

Trenches may be formed to penetrate the second interlayer insulating layers and the second mold patterns ML2 in the first direction D1 and to expose the third substrate 20. The second gate electrodes GE2 may be formed between the second interlayer insulating layers by replacing the second mold patterns ML2, which are exposed by the trenches, with a conductive material. The second mold patterns ML2, which are enclosed by the second dams DAM2, may be left in place without being replaced by the second gate electrodes GE2. The second separation patterns SP2 may be formed to fill inner regions of the trenches.

Second sacrificial layers SAL2 may be formed to fill the second source via hole SH2 and the second plug via holes PH2. In an embodiment, a planarization process may be further performed on upper portions of the second sacrificial layers SAL2, during the formation of the second sacrificial layers SAL2.

At least one of the second cell contact plugs CP2 may be formed to penetrate at least one of the second gate electrodes GE2 in the first direction D1 and to be in contact with one of the second gate electrodes GE2. One of the second cell contact plugs CP2 may be formed to be in contact with the uppermost one of the second gate electrodes GE2. Before the formation of the second cell contact plugs CP2, the insulating spacer IS may be formed in regions where the second cell contact plugs CP2 will be formed.

A first portion 50a of the third insulating layer 50 (e.g., see FIG. 2) may be formed to fully cover the second stack ST2.

The second contact plugs 51 may be formed on top surfaces of the second vertical structures VS2, a top surface of the second sacrificial layer SAL2 filling the second source via hole SH2, top surfaces of the second cell contact plugs CP2, and top surfaces of the second sacrificial layers SAL2 filling the second plug via holes PH2, respectively.

The second common source line CSL2 may be formed to cover top surfaces of the second contact plugs 51, which are in contact with the top surfaces of the second vertical structures VS2, and may be extended to a region on a top surface of the second contact plug 51, which is in contact with the top surface of the second sacrificial layer SAL2 filling the second source via hole SH2.

Each of the second interconnection lines 53 may be formed to cover the top surface of the second contact plug 51, which is in contact with a top surface of the second cell contact plug CP2, and may be extended to a region on the top surface of the second sacrificial layer SAL2 filling the second plug via hole PH2.

The first portion 50a of the third insulating layer 50 (e.g., see FIG. 2) may be formed through two or more distinct steps. The first portion 50a of the third insulating layer 50 (e.g., sec FIG. 2) may be formed at various points in time, taking into account when the steps of forming the second common source line CSL2, the second contact plugs 51, and the second interconnection lines 53 are performed.

Second connection holes CH2 may be formed on the second penetration via holes VH2. The second connection holes CH2 may be vertically overlapped with the second penetration via holes VH2, respectively. A diameter of the second connection holes CH2 may be larger than the diameter of the first connection holes CH1. The second sacrificial layers SAL2 may be formed to fill the second penetration via holes VH2 and the second connection holes CH2. In an embodiment, the second sacrificial layers SAL2 may be formed of or include at least one of C, poly Si, W, or TiN.

Referring to FIG. 13, the second cell array structure CS2 may be inverted vertically, and then, the inverted second cell array structure CS2 may be bonded to the first cell array structure CS1 defining an interface along a bonding surface BS therebetween. A top surface of each of the first sacrificial layers SAL1 may be bonded to a bottom surface of each of the second sacrificial layers SAL2. Accordingly, the second sacrificial layers SAL2 may be vertically overlapped with the first penetration vias TV1, respectively.

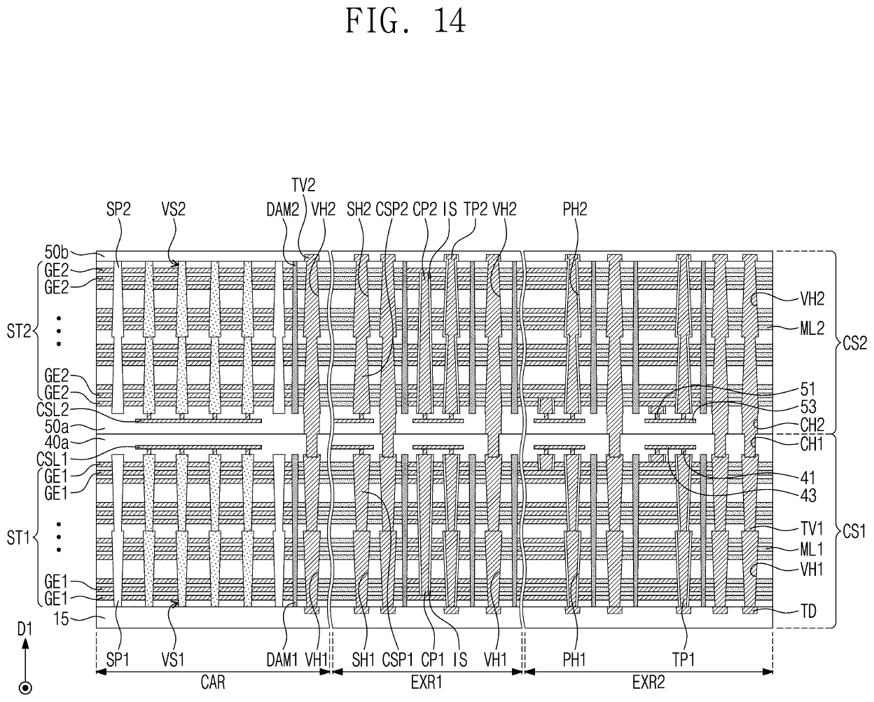

Referring to FIG. 14, the third substrate 20 may be removed, and thus, the second sacrificial layers SAL2 may be exposed externally or to the outside. The exposed second sacrificial layers SAL2 may be removed from regions on the second penetration via holes VH2, the second connection holes CH2, the second source via hole SH2, and the second plug via holes PH2. The first sacrificial layers SAL1 may be removed from regions on the first connection holes CH1.

Thereafter, the second penetration vias TV2 may be formed to fill the second penetration via holes VH2, the first connection holes CH1, and the second connection holes CH2. Each of the second penetration vias TV2 may be formed to be in contact with a corresponding one of the first penetration vias TV1. Accordingly, even when the additional or distinct elements (such as the first and second bonding pads BP1 and BP2 described with reference to FIG. 2) are not provided therebetween, the first and second cell array structures CS1 and CS2 may be electrically connected to each other through the first and second penetration vias TV1 and TV2.

According to an embodiment of the inventive concept, each of the second connection holes CH2 may have a diameter that is larger than a diameter of a corresponding one of the first connection holes CH1. Accordingly, the second penetration vias TV2 may easily fill the first connection holes CH1 and the second connection holes CH2. For example, it may be possible to prevent a void from being formed in the second penetration vias TV2, and thus, the electrical characteristics of the three-dimensional semiconductor memory device may be improved.

The second common source plug CSP2 may be formed to fill the second source via hole SH2. The second penetration plugs TP2 may be formed to fill the second plug via holes PH2. Before the formation of the second penetration plugs TP2, the insulating spacer IS may be formed in the second plug via holes PH2.

A second portion 50b of the third insulating layer 50 (e.g., see FIG. 2) may be formed to fully cover the second stack ST2.

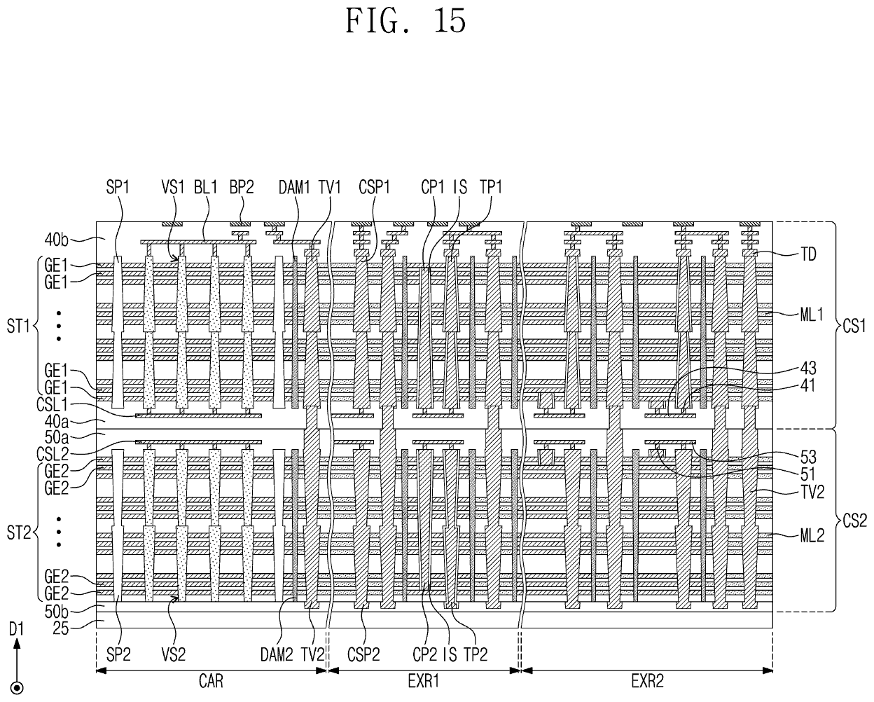

Referring to FIG. 15, the first and second cell array structures CS1 and CS2, which are bonded to each other, may be inverted vertically. The second cell array structure CS2 may be attached to a carrier substrate 25. In an embodiment, the carrier substrate 25 may be a glass substrate or a semiconductor substrate.

The second substrate 15 may be removed. A second portion 40b of the second insulating layer 40 (e.g., see FIG. 2) may be formed to fully cover the first stack ST1.

The second bonding pads BP2 may be formed in an upper portion of the first cell array structure CS1. To electrically connect the second bonding pads BP2 to the first vertical structures VS1 and penetration pads TD, the first contact plugs 41 and the first interconnection lines 43 may be formed in the second portion 40b of the second insulating layer 40 (e.g., sec FIG. 2).

The second portion 40b of the second insulating layer 40 (e.g., see FIG. 2) may be formed through one or more steps. The second portion 40b of the second insulating layer 40 (e.g., sec FIG. 2) may be formed at various points in time, taking into account when the steps of forming the second bonding pads BP2, the first contact plugs 41, and the first interconnection lines 43 are performed. In an embodiment, the second insulating layer 40 (e.g., see FIG. 2) may further include the first interlayer insulating layers, in addition to the first and second portions 40a and 40b.

Referring back to FIG. 2, the first and second cell array structures CS1 and CS2, which are bonded to each other, may be inverted vertically again. Thereafter, the first bonding pads BP1 in the peripheral circuit structure PS may be in contact with the second bonding pads BP2 in the first cell array structure CS1, respectively. Accordingly, the peripheral circuit structure PS and the first and second cell array structures CS1 and CS2 may be bonded to each other.

The carrier substrate 25 may be removed. A third portion (not shown) of the third insulating layer 50 may be formed on the second portion 50b (e.g., see FIG. 15) of the third insulating layer 50. In an embodiment, the third insulating layer 50 may include the first portion 50a (e.g., see FIG. 15), the second portion 50b (e.g., see FIG. 15), the third portion, and the second interlayer insulating layers.

The second bit line BL2, the second interconnection lines 53, and the second contact plugs 51 may be formed in the third insulating layer 50. The protection layer PL may be formed on the third insulating layer 50. The input/output pad IOP may be formed in the protection layer PL.

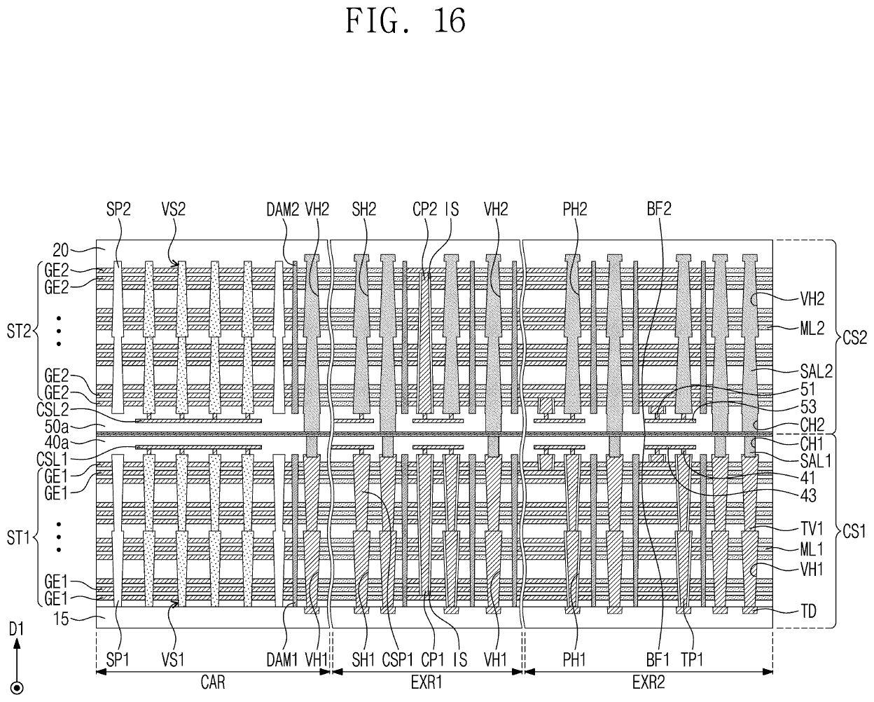

FIG. 16 is a sectional view illustrating a method of fabricating a three-dimensional semiconductor memory device, according to an embodiment of the inventive concept.

Referring to FIG. 16, the first buffer layer BF1 may be formed on the first cell array structure CS1, after the formation of the first sacrificial layers SAL1 described with reference to FIG. 11. Since the first buffer layer BF1 is formed, it may be possible to prevent the top surfaces of the first sacrificial layers SAL1 from being damaged by external causes.

In addition, the second buffer layer BF2 may be formed on the second cell array structure CS2, after the formation of the second sacrificial layers SAL2 described with reference to FIG. 12. Since the second buffer layer BF2 is formed, it may be possible to prevent the top surfaces of the second sacrificial layers SAL2 from being damaged by external causes.

Thereafter, the second cell array structure CS2 may be inverted vertically, and then, the first and second cell array structures CS1 and CS2 may be bonded to each other such that the top surface of the first buffer layer BF1 is in contact with the bottom surface of the second buffer layer BF2.

Referring back to FIG. 5, the third substrate 20 described with reference to FIG. 16 and the second sacrificial layers SAL2 described with reference to FIG. 16 may be removed. Accordingly, a portion of the second buffer layer BF2 described with reference to FIG. 16 may be exposed. The exposed portion of the second buffer layer BF2 and a portion of the first buffer layer BF1 may be removed. Next, the first sacrificial layers SAL1 may be removed.

Thereafter, the method described above may be used to fabricate the remaining portions of the three-dimensional semiconductor memory device described with reference to FIG. 5.

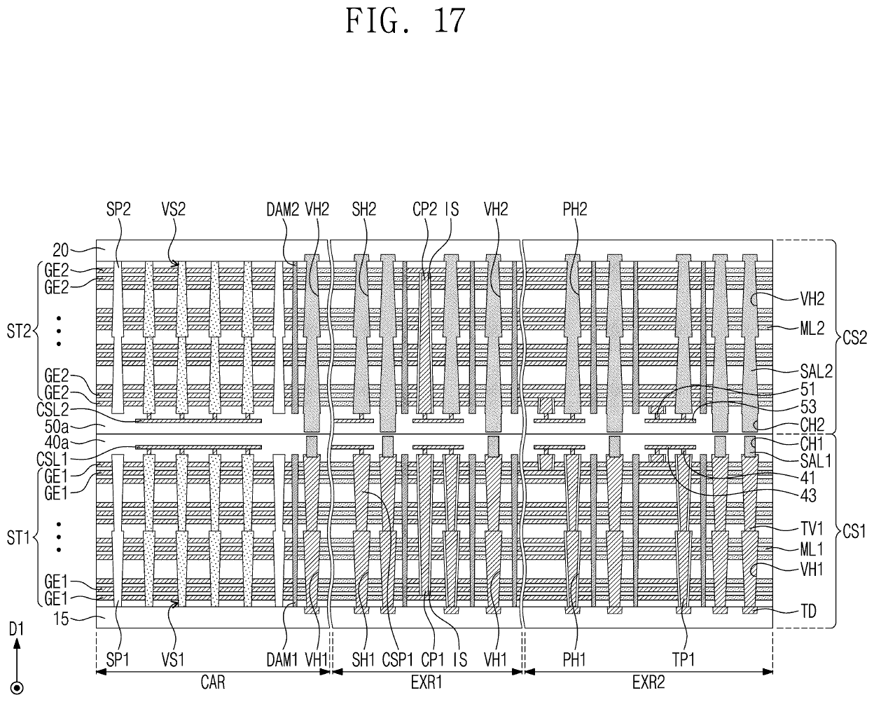

FIG. 17 is a sectional view illustrating a method of fabricating a three-dimensional semiconductor memory device, according to an embodiment of the inventive concept.

Referring to FIG. 17, the first portion 40a of the second insulating layer 40 (e.g., see FIG. 2) may be formed to have a top surface that is located at a higher level than the top surfaces of the first sacrificial layers SAL1 (relative to substrate 15), after the formation of the first sacrificial layers SAL1 described with reference to FIG. 11. In this case, it may be possible to prevent the top surfaces of the first sacrificial layers SAL1 from being damaged by external causes.

After the formation of the second sacrificial layers SAL2 described with reference to FIG. 12, the first portion 50a of the third insulating layer 50 (e.g., see FIG. 2) may be formed to have a top surface that is located at a level higher than the top surfaces of the second sacrificial layers SAL2 (relative to substrate 20). In this case, it may be possible to prevent the top surfaces of the second sacrificial layers SAL2 from being damaged by external causes.

Thereafter, the second cell array structure CS2 may be inverted vertically, and the first and second cell array structures CS1 and CS2 may be bonded to each other.

Referring back to FIG. 7, the third substrate 20 and the second sacrificial layers SAL2 may be removed. A portion of the first portion 50a of the third insulating layer 50 (e.g., see FIG. 2) and a portion of the first portion 40a of the second insulating layer 40 (e.g., see FIG. 2) may be sequentially removed. Next, the first sacrificial layers SAL1 may be removed.

Thereafter, the method described above may be used to fabricate the remaining portions of the three-dimensional semiconductor memory device described with reference to FIG. 7.

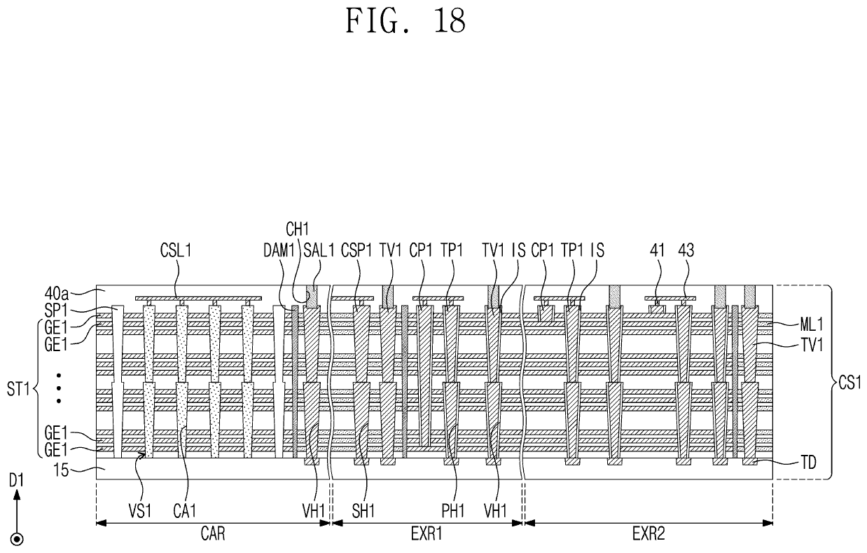

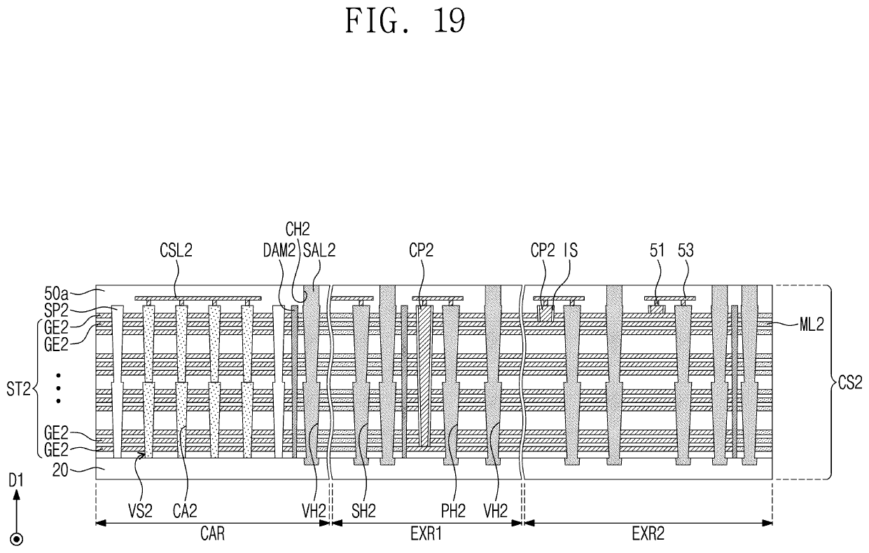

FIGS. 18 and 19 are sectional views illustrating a method of fabricating a three-dimensional semiconductor memory device, according to an embodiment of the inventive concept.

Referring to FIG. 18, in the process of forming the first dams DAM1 described with reference to FIG. 11, the first dams DAM1 may not be formed between the first penetration plug TP1 and the first penetration via TV1 and between the first cell contact plug CP1 and the first penetration via TV1. The first penetration via TV1 adjacent to the first penetration plug TP1 may penetrate the first gate electrodes GE1 in the first direction D1. The insulating spacer IS may be formed on a side surface of the first penetration via TV1 adjacent to the first penetration plug TP1. The first penetration via TV1 adjacent to the first penetration plug TP1 may constitute the first word line penetration via WTV1 described with reference to FIG. 9.

Referring to FIG. 19, in the process of forming the second dams DAM2 described with reference to FIG. 12, the second dams DAM2 may not be formed between the second plug via hole PH2 and the second penetration via hole VH2, which are adjacent to each other, and between the second cell contact plug CP2 and the second penetration via hole VH2. The second sacrificial layers SAL2, which fill the second penetration via hole VH2 adjacent to the second plug via hole PH2, may penetrate the second gate electrodes GE2 in the first direction D1. Next, referring to FIG. 9, the second sacrificial layers SAL2 in the second penetration via hole VH2 adjacent to the second plug via hole PH2 may be replaced with the second penetration via TV2. The second penetration via TV2 may constitute the second word line penetration via WTV2.

Thereafter, the method described above may be used to fabricate the remaining portions of the three-dimensional semiconductor memory device described with reference to FIG. 9.

According to an embodiment of the inventive concept, a second penetration via may be in contact with a top surface of a first penetration via in a first cell array structure and may be extended into a second cell array structure, in a first direction, on the top surface of the first penetration via. Since the first and second penetration vias are in direct contact with each other without separate or distinct intervening elements (such as first and second bonding pads) therebetween, each of a second bit line, a second common source line, a second cell contact plug, and an input/output pad may be electrically connected to a peripheral circuit structure through the first and second penetration vias. As a result, it may be possible to omit a process of forming the separate or distinct intervening elements, such as the first and second bonding pads, and to simplify a fabrication process. Thus, it may be possible to improve productivity in fabricating a three-dimensional semiconductor memory device.

In addition, since the first and second penetration vias are in direct contact with each other without the separate or distinct intervening elements (such as the first and second bonding pads) therebetween, an electrical resistance between the first and second penetration vias may be reduced. Thus, the electrical characteristics of the three-dimensional semiconductor memory device may be improved.

According to an embodiment of the inventive concept, second connection holes may be formed to have diameters that are larger than those of first connection holes. Accordingly, an inner space of each of the first and second connection holes may be more easily filled with the second penetration via. As a result, a void may not be formed in the second penetration vias, and the electrical characteristics of the three-dimensional semiconductor memory device may be improved.

While example embodiments of the inventive concept have been particularly shown and described, it will be understood by one of ordinary skill in the art that variations in form and detail may be made therein without departing from the scope of the appended claims.

What is claimed is:

1. A three-dimensional (3D) semiconductor memory device, comprising:
a first cell array structure on a substrate, the first cell array structure comprising a plurality of first gate electrodes, which are stacked in a first direction perpendicular to a top surface of the substrate;
a second cell array structure on the first cell array structure, the second cell array structure comprising a plurality of second gate electrodes, which are stacked in the first direction;
a first penetration via in the first cell array structure and extending in the first direction; and
a second penetration via that is in contact with a surface of the first penetration via that is in the first cell array structure, wherein the second penetration via extends from the surface of the first penetration via into the second cell array structure in the first direction.

2. The 3D semiconductor memory device of claim 1, wherein the first cell array structure comprises a first vertical structure extending into the first gate electrodes in the first direction,
wherein the second cell array structure comprises a second vertical structure extending into the second gate electrodes in the first direction, and
wherein the first vertical structure and the second vertical structure are spaced apart from each other in the first direction.

3. The 3D semiconductor memory device of claim 1, wherein the first cell array structure comprises a first vertical structure extending into the first gate electrodes in the first direction,
wherein the second cell array structure comprises a second vertical structure extending into the second gate electrodes in the first direction, and
wherein the first vertical structure and the second vertical structure are symmetrical with respect to an interface between the first cell array structure and the second cell array structure.

4. The 3D semiconductor memory device of claim 1, wherein the second penetration via comprises a penetration portion, a connecting portion between the penetration portion and the first penetration via, and a barrier pattern extending around the penetration portion and the connecting portion.

5. The 3D semiconductor memory device of claim 4, wherein the barrier pattern is between the connecting portion and the first penetration via.

6. The 3D semiconductor memory device of claim 4, wherein a sidewall of the connecting portion comprises a step difference between an upper portion and a lower portion thereof.

7. The 3D semiconductor memory device of claim 4, wherein a width of an upper portion of the connecting portion is greater than a width of a lower portion thereof, in a direction parallel to the top surface of the substrate.

8. The 3D semiconductor memory device of claim 4, wherein the penetration portion vertically overlaps with each of the connecting portion and the first penetration via.

9. The 3D semiconductor memory device of claim 4, wherein the penetration portion and the connecting portion are a unitary member.

10. The 3D semiconductor memory device of claim 1, further comprising:
a peripheral circuit structure between the substrate and the first cell array structure,
wherein the second penetration via is electrically connected to the peripheral circuit structure through the first penetration via.

11. The 3D semiconductor memory device of claim 1, wherein, in a second direction perpendicular to the first direction, a width of a portion of the second penetration via decreases with distance from the top surface of the substrate in the first direction.

12. The 3D semiconductor memory device of claim 1, wherein, in a second direction perpendicular to the first direction, a width of a portion of the first penetration via increases with distance from the top surface of the substrate in the first direction.

13. The 3D semiconductor memory device of claim 1, wherein the second cell array structure further comprises:
a second vertical structure extending into the second gate electrodes, and
a vertical length of the second penetration via is greater than a vertical length of the second vertical structure in the first direction.

14. A three-dimensional (3D) semiconductor memory device, comprising:
a peripheral circuit structure on a substrate;
a first cell array structure on the peripheral circuit structure, the first cell array structure comprising a first stack including a plurality of first gate electrodes that are stacked in a first direction perpendicular to a top surface of the substrate;
a second cell array structure on the first cell array structure, the second cell array structure comprising a second stack including a plurality of second gate electrodes that are stacked in the first direction;
a first penetration via extending into the first stack in the first direction; and
a second penetration via extending into the second stack in the first direction,
wherein the second penetration via is in contact with a surface of the first penetration via and is electrically connected to the peripheral circuit structure through the first penetration via.

15. The 3D semiconductor memory device of claim 14, wherein the second penetration via comprises a penetration portion and a connecting portion that is between the penetration portion and the first penetration via, and
a sidewall of the connecting portion comprises a step difference between an upper portion and a lower portion thereof.

16. The 3D semiconductor memory device of claim 15, wherein the second penetration via further comprises a barrier pattern between the connecting portion and the first penetration via.

17. The 3D semiconductor memory device of claim 14, wherein the first cell array structure further comprises a first vertical structure extending into the first gate electrodes in the first direction,
wherein the second cell array structure further comprises a second vertical structure extending into the second gate electrodes in the first direction, and
wherein the first vertical structure and the second vertical structure are spaced apart from each other in the first direction.

18. The 3D semiconductor memory device of claim 14, wherein the first cell array structure further comprises a first vertical structure extending into the first gate electrodes in the first direction,
wherein the second cell array structure further comprises a second vertical structure extending into the second gate electrodes in the first direction, and
wherein the first vertical structure and the second vertical structure are symmetrical with respect to an interface between the first cell array structure and the second cell array structure.

19. An electronic system, comprising:
a three-dimensional semiconductor memory device; and
a controller that is electrically connected to the three-dimensional semiconductor memory device through an input/output pad and is configured to control the three-dimensional semiconductor memory device,
wherein the three-dimensional semiconductor memory device comprises:
a first cell array structure on a substrate, the first cell array structure comprising a plurality of first gate electrodes that are stacked in a first direction perpendicular to a top surface of the substrate;
a second cell array structure on the first cell array structure, the second cell array structure comprising a plurality of second gate electrodes that are stacked in the first direction;
a first penetration via in the first cell array structure and extending in the first direction;
a second penetration via that is in contact with a surface of the first penetration via in the first cell array structure, wherein the second penetration via extends from the surface of the first penetration via into the second cell array structure in the first direction.

20. The electronic system of claim 19, further comprising:
a peripheral circuit structure between the substrate and the first cell array structure,
wherein the second penetration via is electrically connected to the peripheral circuit structure through the first penetration via.
